(19) United States
(12) Patent Application Publication
(10) Pub. No.: US 2026/0082965 A1
(43) Pub. Date: Mar. 19, 2026

(54) MICROELECTRONIC ASSEMBLIES INCLUDING A GLASS-CORE WITH POST-SINGULATION EDGE FEATURES

(71) Applicant: Intel Corporation, Santa Clara, CA (US)

(72) Inventors: Brandon C. Marin, Gilbert, AZ (US); Sheng Li, Gilbert, AZ (US); Srinivas Venkata Ramanuja Pietambaram, Chandler, AZ (US); Gang Duan, Chandler, AZ (US); Jeremy Ecton, Gilbert, AZ (US); Hiroki Tanaka, Gilbert, AZ (US); Bai Nie, Chandler, AZ (US); Jianyong Mo, Chandler, AZ (US); Naiya Soetan-Dodd, Mesa, AZ (US); Fanyi Zhu, Gilbert, AZ (US); Bohan Shan, Chandler, AZ (US); Yi Li, Chandler, AZ (US); Hanyu Song, Chandler, AZ (US); Mohamed R. Saber, College Station, TX (US); Shuren Qu, Gilbert, AZ (US); Molla Shakirul Islam, Chandler, AZ (US)

(73) Assignee: Intel Corporation, Santa Clara, CA (US)

(21) Appl. No.: 18/888,428

(22) Filed: Sep. 18, 2024

(51) Int. Cl. H01L 23/13; H01L 23/00; H01L 23/15; H01L 23/498; H01L 25/18; H05K 1/18; H10B 80/00

(52) U.S. Cl. CPC H10W 70/68; H10W 70/692; H10W 90/401; H05K 1/181; H10B 80/00; H10W 42/121; H10W 72/0198; H10W 72/823; H10W 74/15; H10W 90/00; H10W 90/722; H10W 90/724; H10W 90/734

(57) ABSTRACT

Disclosed herein are microelectronic assemblies and related devices and methods for alleviating crack formation and propagation in glass by providing various edge features during or after singulation of a glass panel into individual glass units. In some embodiments, a microelectronic assembly includes a glass core (e.g., a layer of glass including a rectangular prism volume) having a first face, a second face opposite the first face, and an edge between an end of the first face and an end of the second face, and further includes a protection coating on the edge, where a material of the protection coating includes a low-density polystyrene foam, an ionogel, a fiber reinforced resin, a pre-impregnated dielectric, a pre-impregnated fabric, a carbon nanotube reinforced epoxy resin, a metal oxide, a mold material, or a solder resist.

### BACKGROUND

For the past several decades, scaling of features in integrated circuits (ICs) has been a driving force behind an ever-growing semiconductor industry and emerging applications in fields such as big data, artificial intelligence, mobile communications, and autonomous driving. Scaling to smaller and smaller features enables increased densities of functional units on the limited real estate of semiconductor chips. For example, shrinking transistor size allows incorporation of an increased number of memory or logic devices on a chip, lending to the fabrication of products with increased capacity. The drive for the ever-increasing capacity, however, is not without issue. The necessity to optimize fabrication and performance of each component (e.g., of each transistor) is becoming increasingly significant.

Parallel to optimizations at the transistor level, advanced IC packaging landscape is rapidly evolving to accommodate performance expectations and requirements of shrinking transistor size. Multiple IC dies are now commonly coupled together in a multi-die IC package to integrate features or functionality and to facilitate connections to other components, such as package substrates. For example, IC packages may include an embedded multi-die interconnect bridge (EMIB) for coupling two or more IC dies.

Integration of multiple dies in a single IC package has tremendous benefits but adds additional complexities due to placing materials with different material properties in close proximity to one another. When an IC package undergoes multiple processing steps involving various temperatures and pressure loads, individual materials within the package may behave differently from one another, resulting in out of plane deformation of various layers, known as “package warpage.” One way to address package warpage is to use stiffer cores to which different IC dies are attached. Recently, glass cores have been explored as alternatives to organic resin-based cores (e.g., cores based on using Ajinomoto Build-up Film (ABF)). Glass is considered more rigid than organic resin-based materials and has several advantages such as excellent thermal properties, low coefficient of thermal expansion (CTE), high electrical insulation, chemical resistance, optical transparency, and compatibility with advances semiconductor properties. However, a major challenge for widespread adoption of glass cores is the fact that glass is highly susceptible to damage due to mechanical and/or thermal stresses.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a schematic cross-sectional view of an example microelectronic assembly according to some embodiments of the present disclosure.

FIGS. 2A-2E are simplified cross-sectional views illustrating various manufacturing steps of an example microelectronic assembly according to some embodiments of the present disclosure.

FIGS. 3A-3C are simplified schematic cross-sectional views of example portions of microelectronic assemblies according to some embodiments of the present disclosure.

FIG. 4 is a schematic cross-sectional view of another example microelectronic assembly according to some embodiments of the present disclosure.

FIG. 5 is a schematic cross-sectional view of yet another example microelectronic assembly according to some embodiments of the present disclosure.

FIGS. 6A-6F are simplified top views illustrating various manufacturing steps of the example microelectronic assembly of FIG. 5 according to some embodiments of the present disclosure.

FIGS. 7A and 7B are schematic cross-sectional views of other example microelectronic assemblies according to some embodiments of the present disclosure.

FIGS. 8A-8D are simplified top views illustrating various manufacturing steps of the example microelectronic assembly of FIG. 7A according to some embodiments of the present disclosure.

FIGS. 9A and 9B are simplified top views illustrating various manufacturing steps of the example microelectronic assembly of FIG. 7B according to some embodiments of the present disclosure.

FIG. 10 is a schematic cross-sectional view of another example microelectronic assembly according to some embodiments of the present disclosure.

FIGS. 11A-11E are simplified side/top views illustrating various manufacturing steps of the example microelectronic assembly of FIG. 10 according to some embodiments of the present disclosure.

FIGS. 12A-12D are simplified side views illustrating other various manufacturing steps of the example microelectronic assembly of FIG. 10 according to some embodiments of the present disclosure.

FIG. 13A is a schematic cross-sectional view of another example microelectronic assembly according to some embodiments of the present disclosure.

FIG. 13B is a schematic perspective view of the example microelectronic assembly of FIG. 13A according to some embodiments of the present disclosure.

FIGS. 14A-14C are simplified cross-sectional views illustrating various manufacturing steps of the example microelectronic assembly of FIG. 15 according to some embodiments of the present disclosure.

FIG. 15 is a schematic cross-sectional view of another example microelectronic assembly according to some embodiments of the present disclosure.

FIGS. 16A and 16B illustrate a process of healing cracks using an edge protection coating with a crack-healing material according to some embodiments of the present disclosure.

FIG. 17 is a cross-sectional view of a device package that may include one or more microelectronic assemblies in accordance with any of the embodiments disclosed herein.

FIG. 18 is a cross-sectional side view of a device assembly that may include one or more microelectronic assemblies in accordance with any of the embodiments disclosed herein.

FIG. 19 is a block diagram of an example computing device that may include one or more microelectronic assemblies in accordance with any of the embodiments disclosed herein.

### DETAILED DESCRIPTION

The structures and assemblies disclosed herein may include a glass core, also referred to herein as a “glass layer,” with through-glass vias (TGVs) extending through the glass core for front-to-back connections between two different substrates. A substrate may include a dielectric material with conductive pathways therein that are typically formed on a surface of the glass core. The conductive pathways through the dielectric material may provide routing for design flexibility, and the uniform diameters of the TGVs may provide dimensional stability and improved connectivity. A glass core as compared to a conventional epoxy core offers several advantages including higher through-glass via (TGV) density, lower signal losses, and lower total thickness variation (TTV), among others. Another advantage is a glass core enables higher aspect ratio TGVs. Higher aspect ratio TGVs are required to achieve the finer pitches that are desired.

As mentioned above, a major challenge for widespread adoption of glass cores is the fact that glass is highly susceptible to damage due to mechanical and/or thermal stresses. One source of mechanical and thermal stresses in glass is the singulation process (sometimes referred to as “dicing” or “cutting”) that takes place during manufacturing of glass cores. Singulation is a process in which a substrate panel is cut into smaller units, for example, quarter panel level or unit level. The process for substrates with a glass core is different than an organic core. For an organic core, a two-step laser process is used to cut the glass to the point where only a small, perforated amount of material is holding the panel together. A mechanical break step is used to complete the separation. The break step applies mechanical force to the surface of a glass panel in order to separate (e.g., dice or cut) the panel into individual glass units having a smaller form factor than the panel. The mechanical force applied by the cutting tool may create a localized stress concentration (e.g., regions of higher stress) at or near the surfaces where the cutting tool contacts the glass, e.g., at or near the edges of the individual glass units, where, as used herein, the term “edge” refers to a side/sidewall/lateral surface that is between top and the bottom surfaces of a glass unit, a glass core, or glass panel. Because glass is a brittle material characterized by its lack of ductility (e.g., characterized by its limited ability to undergo significant plastic deformation before fracturing), localized stress concentration often leads to formation of cracks at the edges of singulated glass units. Besides imposing mechanical stress onto glass, singulation can also generate thermal stress due to friction between the cutting tool and glass, heating up the surface being cut. The heat can cause localized expansion and contraction of glass, further promoting crack formation and propagation.

Singulation is not the only source of stress and damage that may affect glass cores. Presence of materials with different CTEs on top and/or on the bottom of glass cores (e.g., metals of conductive pathways and/or dielectric materials of build-up layers) adds to the stresses in glass (such stresses referred to as “CTE mismatch-induced stresses”), further exacerbating the problem of crack formation. Even if cracks don't form immediately during singulation, cutting of brittle materials like glass often results in individual glass units with edges that are rough, jagged, or otherwise uneven. Repeated thermal cycling during operation of microelectronic assemblies that include glass cores with such edges can gradually weaken the glass surface due to CTE mismatch-induced stresses, leading to formation of cracks at that time. Furthermore, even before singulation, glass may have tiny surface flaws or defects, which can act as initiation points for crack formation, with additional mechanical and/or thermal stresses increasing the severity of crack growth.

Once cracks start to form, they tend to propagate through glass, with additional mechanical and/or thermal stresses increasing the severity of crack propagation. In particular, the stress concentration at the edges of the glass units encourages the cracks to extend further into glass, and the inherent brittleness of glass makes it particularly susceptible to crack propagation. Propagation of cracks may even cause a glass volume to split into two halves around a plane parallel to the top/bottom surfaces of the glass volume and being about in the middle of the glass volume, one half being the bottom half and the other half being the top half of what is supposed to be a single structure.

As the foregoing illustrates, crack formation and propagation in glass compromises the structural integrity of glass, making microelectronic assemblies with glass cores particularly prone to failure over time. Embodiments of the present disclosure relate to various techniques, as well as to related devices and methods, for alleviating (e.g., mitigating or reducing) crack formation and propagation in glass. In particular, embodiments of the present disclosure are based on providing various edge features after singulation of a glass panel into individual glass units. Because these edge features are detectable after singulation, they may be referred to as “post-singulation” edge features. The individual glass units can serve as glass cores of microelectronic assemblies, and the edge features can help mitigate or reduce crack formation and/or propagation in glass cores. As used herein, an “edge feature” refers to any feature located at or near an edge of a glass core (e.g., of a glass unit after singulation). For example, in one aspect of the present disclosure, a microelectronic assembly includes a glass core (e.g., a layer of glass including a rectangular prism volume) having a first face, a second face opposite the first face, and an edge between an end of the first face and an end of the second face, and further includes a protection coating on the edge, where a material of the edge protection coating includes, but is not limited to, a low-density polystyrene foam, an ionogel, a fiber reinforced resin, a pre-impregnated dielectric, such as FR4, a pre-impregnated fabric, such as Glass Cloth Prepreg (GCP) material, a carbon nanotube (CNT) reinforced epoxy resin, a metal oxide, a mold material, or a solder resist. In another aspect, a microelectronic assembly includes a glass core as in the first aspect and further includes the protection coating at least partially on the first face and the second face of the glass core adjacent to the edge. In yet another aspect, a microelectronic assembly includes a glass core with edges that have undergone thermal and/or chemical treatment.

Integration of layers of different materials (e.g., multiple dies, redistribution layers, package substrates) in a single IC package or a microelectronic assembly is challenging due to package warpage, among others. Providing IC packages or microelectronic assemblies with glass cores having one or more edge features as described herein may help. Various ones of the embodiments disclosed herein may help achieve reliable integration of multiple layers of different materials within a single microelectronic assembly at a lower cost and/or with greater design flexibility, relative to conventional approaches. Various ones of the microelectronic assemblies disclosed herein may exhibit reduced warpage, relative to microelectronic assemblies without glass cores. The microelectronic assemblies disclosed herein may be particularly advantageous for small and low-profile applications in computers, tablets, industrial robots, and consumer electronics (e.g., wearable devices).

Accordingly, disclosed herein are microelectronic assemblies and related devices and methods. In some embodiments, a microelectronic assembly may include a glass core having a first face, a second face opposite the first face, and an edge between an end of the first face and an end of the second face, and further includes a protection coating on the edge, where a material of the protection coating includes a low-density polystyrene foam, an ionogel, a fiber reinforced resin, a pre-impregnated dielectric, a pre-impregnated fabric, a carbon nanotube reinforced epoxy resin, a metal oxide, a mold material, or a solder resist.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are stated in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may include substantially monocrystalline semiconductors, such as silicon or germanium, as a base material on which integrated circuits are fabricated with traditional semiconductor processing methods. The semiconductor base material may include, for example, N-type or P-type materials. Dies may include, for example, a crystalline base material formed using a bulk silicon (or other bulk semiconductor material) or a semiconductor-on-insulator (SOI, e.g., a silicon-on-insulator) structure. In some other embodiments, the base material of one or more of the IC dies may include alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may include compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may include an intrinsic IV or III-V semiconductor material or alloy, not intentionally doped with any electrically active impurity; in alternate embodiments, nominal impurity dopant levels may be present. In still other embodiments, dies may include a non-crystalline material, such as polymers; for example, the base material may include silica-filled epoxy. In other embodiments, the base material may include high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of input/output (I/O) functions, arithmetic operations, pipelining of data, etc.).

In another example, the terms “package” and “IC package” are synonymous, as are the terms “die” and “IC die.” Note that the terms “chip,” “chiplet,” “die,” and “IC die” are used interchangeably herein.

The term “optical structure” includes arrangements of forms fabricated in ICs to receive, transform and/or transmit optical signals as described herein. It may include optical conductors such as waveguides, electromagnetic radiation sources such as lasers and light-emitting diodes (LEDs) and electro-optical devices such as photodetectors.

In various embodiments, any photonic IC (PIC) described herein may include a semiconductor material, for example, N-type or P-type materials. The PIC may include, for example, a crystalline base material formed using a bulk silicon (or other bulk semiconductor material) or a SOI structure (or, in general, a semiconductor-on-insulator structure). In some embodiments, the PIC may be formed using alternative materials, which may or may not be combined with silicon, that include, but are not limited to, lithium niobite, indium phosphide, silicon dioxide, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-N or group IV materials. In some embodiments, the PIC may include a non-crystalline material, such as polymers. In some embodiments, the PIC may be formed on a printed circuit board (PCB). In some embodiments, the PIC may be inhomogeneous, including a carrier material (such as glass or silicon carbide) as a base material with a thin semiconductor layer over which is an active side comprising transistors and like components. Although a few examples of the material for the PIC are described here, any material or structure that may serve as a foundation upon which the PIC may be built falls within the spirit and scope of the present disclosure.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field-effect transistors (FETs), e.g., metal oxide semiconductor (MOS) FETs (MOSFETs). In general, a FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are included in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a PIC, “interconnect” may also describe any element formed of a material that is optically conductive for providing optical connectivity to one or more elements associated with the PIC. In such cases, the term “interconnect” may refer to optical waveguides (e.g., structures that guide and confine light waves), including optical fiber, optical splitters, optical combiners, optical couplers, and optical vias.

The term “waveguide” refers to any structure that acts to guide the propagation of light from one location to another location typically through a substrate material such as silicon or glass. In various examples, waveguides can be formed from silicon, doped silicon, silicon nitride, glasses such as silica (e.g., silicon dioxide or SiO2), borosilicate (e.g., 70-80 wt % SiO2, 7-13 wt % of B2O3, 4-8 wt % Na2O or K2O, and 2-8 wt % of Al2O3) and so forth. Waveguides may be formed using various techniques including but not limited to forming waveguides in situ. For example, in some embodiments, waveguides may be formed in situ in glass using low temperature glass-to-glass bonding or by laser direct writing. Waveguides formed in situ may have lower loss characteristics.

The term “conductive trace” may be used to describe an electrically conductive element isolated by an insulating material. Within IC dies, such insulating material includes interlayer low-k dielectric that is provided within the IC die. Within package substrates, and printed circuit boards (PCBs) such insulating material includes organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes buildup layers (e.g., ABF layers).

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

In context of a stack of dies coupled to one another or in context of a die coupled to a package substate, the term “interconnect” may also refer to, respectively, die-to-die (DTD) interconnects and die-to-package substrate (DTPS) interconnects. DTD interconnects may also be referred to as first-level interconnects (FLI). DTPS interconnects may also be referred to as Second-Level Interconnects (SLI). Although not specifically shown in all of the present illustrations in order to not clutter the drawings, when DTD or DTPS interconnects are described, a surface of a first die may include a first set of conductive contacts, and a surface of a second die or a package substrate may include a second set of conductive contacts. One or more conductive contacts of the first set may then be electrically and mechanically coupled to some of the conductive contacts of the second set by the DTD or DTPS interconnects. In some embodiments, the pitch of the DTD interconnects may be different from the pitch of the DTPS interconnects, although, in other embodiments, these pitches may be substantially the same.

It will be recognized that one more levels of underfill (e.g., organic polymer material such as benzotriazole, imidazole, polyimide, or epoxy) may be provided in an IC package described herein and may not be labeled in order to avoid cluttering the drawings. In various embodiments, the levels of underfill may include the same or different insulating materials. In some embodiments, the levels of underfill may include thermoset epoxies with silicon oxide particles; in some embodiments, the levels of underfill may include any suitable material that can perform underfill functions such as supporting the dies and reducing thermal stress on interconnects. In some embodiments, the choice of underfill material may be based on design considerations, such as form factor, size, stress, operating conditions, etc. ; in other embodiments, the choice of underfill material may be based on material properties and processing conditions, such as cure temperature, glass transition temperature, viscosity and chemical resistance, among other factors; in some embodiments, the choice of underfill material may be based on both design and processing considerations.

In some embodiments, one or more levels of solder resist (e.g., epoxy liquid, liquid photoimageable dielectrics, dry film photoimageable dielectrics, acrylics, solvents) may be provided in an IC package described herein and may not be labeled or shown to avoid cluttering the drawings. Solder resist may be a liquid or dry film material including photoimageable dielectrics. In some embodiments, solder resist may be non-photoimageable.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

Coordinates, when included in the accompanying drawings, identify a thickness or a height by z-dimension, a width by y-dimension, and a length by x-dimension. A diameter or cross section may be identified by xy-dimension.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond-pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

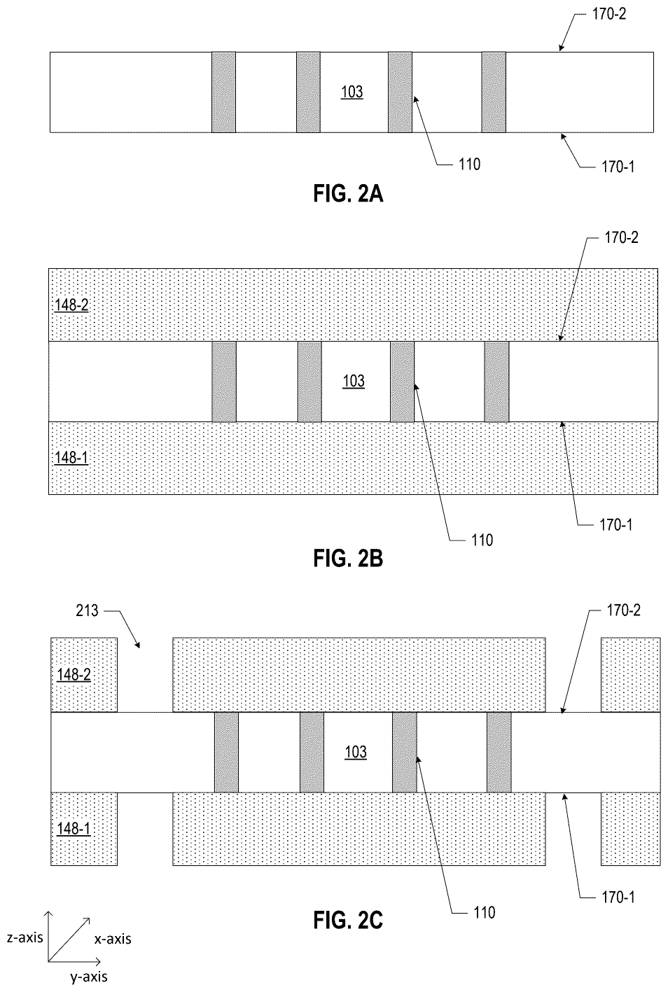

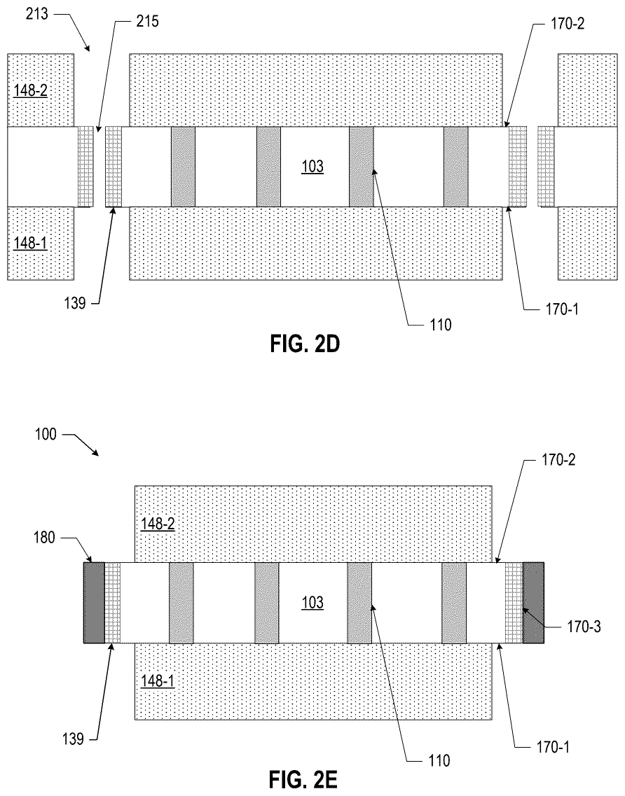

For convenience, if a collection of drawings designated with different letters are present (e.g., FIGS. 2A-2E), such a collection may be referred to herein without the letters (e.g., as “FIG. 2”). Similarly, if a collection of reference numerals designated with different numbers and/or letters are present (e.g., 148-1, 148-2), such a collection may be referred to herein without the numbers (e.g., as “148”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

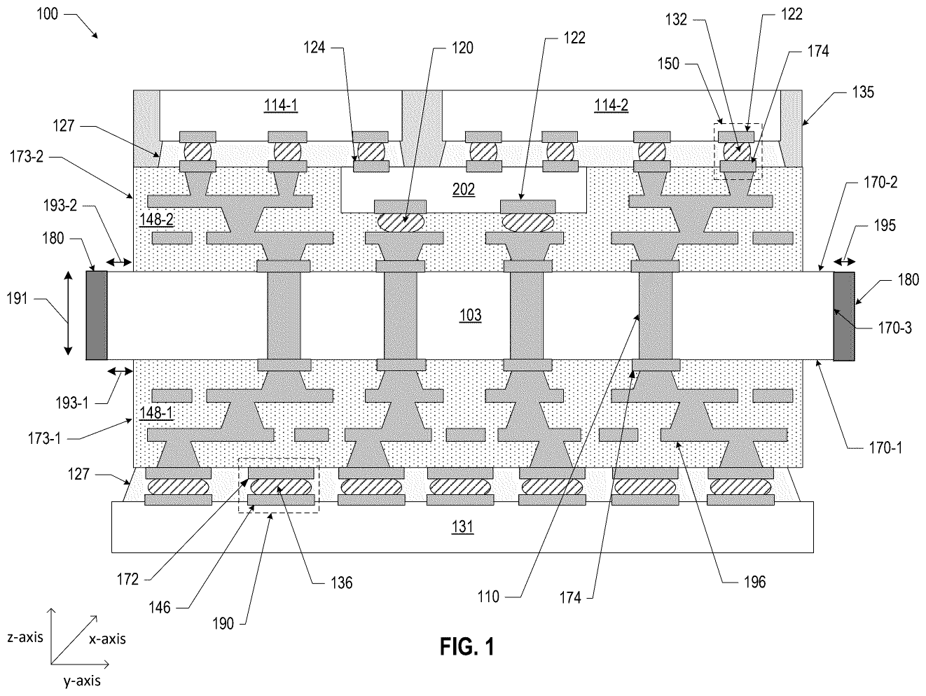

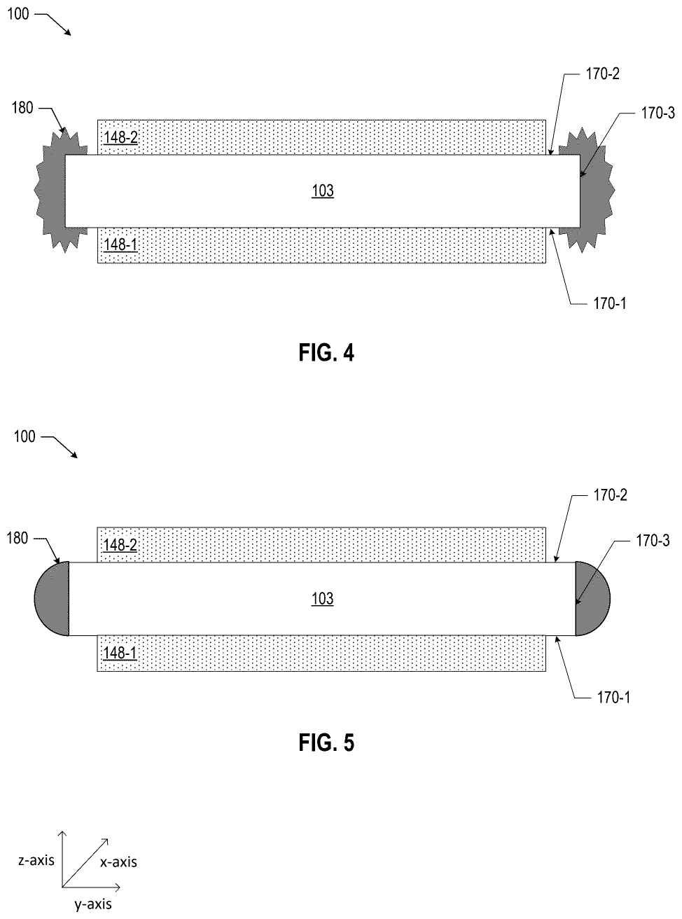

FIG. 1 is a schematic cross-sectional view of an example microelectronic assembly 100 according to some embodiments of the present disclosure. Microelectronic assembly 100 may include a glass core 103 having a first surface 170-1, a second surface 170-2 opposite the first surface 170-1, an edge 170-3 extending between the first surface 170-1 and the second surface 170-2, and an edge protection coating 180 on the edge 170-3. A material of the edge protection coating 180 may include a low-density polystyrene foam, an ionogel, a fiber reinforced resin, a pre-impregnated dielectric, a pre-impregnated fabric, a CNT reinforced epoxy resin, a metal oxide, a mold material, or a solder resist. An edge protection coating 180 may have any suitable profile and any suitable dimensions, which may partially depend on the process used for depositing the edge protection coating 180, as described below with reference to FIGS. 4-16. In some embodiments, a width 195 (e.g., y-dimension) of the edge protection coating 180 may be between about 1 nanometer and 100 microns (e.g., between about 10 nanometers and 50 microns or between about 50 nanometers and 1 micron).

A glass core 103 may have an overall thickness 191 (e.g., z-dimension or z-height) between 50 microns and 2 millimeters (i.e., between 200 microns and 1 millimeter). An edge 170-3 of the glass core 103 may extend beyond a lateral surface 173-1 of a first substrate 148-1 and a lateral surface 173-2 of a second substrate 148-2. An edge 170-3 may extend out beyond a lateral surface 173-1, 173-2 of the first and second substrate 148-1, 148-2, respectively, by a width (e.g., y-dimension) 193 between 1 micron and 200 microns. In some embodiments, a first width 193-1 and a second width 193-2 are substantially the same. In some embodiments, a first width 193-1 and a second width 193-2 are different (e.g., have different values).

A glass core 103 may further include TGVs 110. TGVs 110 may have any suitable size and shape. A thickness (e.g., z-dimension) of the individual TGVs 110 may be between 50 microns and 2 millimeters (i.e., between 200 microns and 1 millimeter). A diameter (e.g., xy-dimension) of the individual TGVs 110 may be between 5 microns and 100 microns (e.g., between 20 microns and 50 microns). TGVs 110 are shown in FIG. 1 as having straight sides; however, in various embodiments, the TGVs 110 may have sides that taper toward a middle (e.g., have an hourglass shape), and/or have other irregularities depending on the processing conditions for generating TGVs 110. TGVs 110 may be formed using any suitable process, including, for example, via openings may be formed by laser activation and wet etch, laser ablation, or laser drilling, and a conductive material may be deposited in the via openings. TGVs 110 may be formed of any suitable conductive material, such as copper, silver, nickel, gold, aluminum, or other metals or alloys. In some embodiments, a pitch of the TGVs 110 may be between 25 microns and 200 microns (e.g., between 75 microns and 150 microns).

A material of the glass core 103 may include glass, such as bulk transparent glass, and also may be referred to herein as “a glass layer.” As used herein, the term “core” refers to a structure (e.g., a portion of a glass layer) of any glass material such as quartz, silica, fused silica, silicate glass (e.g., borosilicate, aluminosilicate, alumino-borosilicate), soda-lime glass, soda-lime silica, borofloat glass, lead borate glass, photosensitive glass, non-photosensitive glass, or ceramic glass. In particular, the glass core 103 may be bulk glass or a solid volume/layer of glass, as opposed to, e.g., materials that may include particles of glass, such as glass fiber reinforced polymers. Such glass materials are typically non-crystalline, often transparent, amorphous solids. In some embodiments, the glass core 103 may be an amorphous solid glass layer. In some embodiments, the glass core 103 may include silicon and oxygen, as well as any one or more of aluminum, boron, magnesium, calcium, barium, tin, sodium, potassium, strontium, phosphorus, zirconium, lithium, titanium, and zinc. In some embodiments, the glass core 103 may include a material, e.g., any of the materials described above, with a weight percentage of silicon being at least about 0.5%, e.g., between about 0.5% and 50%, between about 1% and 48%, or at least about 23%. For example, if the glass core 103 is fused silica, the weight percentage of silicon may be about 47%. In some embodiments, the glass core 103 may include at least 23% silicon and/or at least 26% oxygen by weight, and, in some further embodiments, the glass core 103 may further include at least 5% aluminum by weight. In some embodiments, the glass core 103 may include any of the materials described above and may further include one or more additives such as Al₂O₃, B₂O₃, MgO, CaO, SrO, BaO, SnO₂, Na₂O, K₂O, SrO, P₂O₃, ZrO₂, Li₂O, Ti, and Zn. In some embodiments, the glass core 103 may be a layer of glass that does not include an organic adhesive or an organic material. The glass core 103 may be distinguished from, for example, the “prepreg” or “RF4” core of a PCB substrate which typically includes glass fibers embedded in a resinous organic material such as an epoxy. In some embodiments, a cross-section of the glass core 103 in an xz plane, an yz plane, and/or an xy plane of an example coordinate system, shown in FIG. 1, may be substantially rectangular.

The microelectronic assembly 100 may further include a first substrate 148-1 at the first surface 170-1 of the glass core 103 and a second substrate 148-2 at the second surface 170-2 of the glass core 103. The first and second substrates 148-1, 148-2 may include conductive pathways 196 (e.g., including conductive traces and/or conductive vias, as shown) through a dielectric material. The substrates 148 may include a set of first conductive contacts 172 at the bottom surface of the substrate 148 and a set of second conductive contacts 174 at the top surface of the substrate 148, where the conductive pathways 196 electrically couple individual ones of the first and second conductive contacts 172, 174. In some embodiments, conductive contacts 174, 172 at respective first and second surfaces 170-1, 170-2 of the core 103 may be omitted.

The first and second substrates 148-1, 148-2 may be manufactured using any suitable technique, such as a semi-additive process, a subtractive etching technique, or other conventional substrate package techniques. In some embodiments, a dielectric material of the substrate 148 may include bismaleimide triazine (BT) resin, polyimide materials, epoxy materials (e.g., glass reinforced epoxy matrix materials, epoxy build-up films, or the like), mold materials, oxide-based materials (e.g., silicon dioxide or spin on oxide), or low-k and ultra low-k dielectric (e.g., carbon-doped dielectrics, fluorine-doped dielectrics, porous dielectrics, and organic polymeric dielectrics). The TGVs 110 in the glass core 103 may electrically couple the first and second substrates 148-1, 148-2. As used herein, the glass core 103 with the second substrate 148-2 and/or the first substrate 148-1 may be referred to as a package substrate. TGVs 110 in glass core 103 may enable power, ground and signal connectivity to components located on either side of the glass core 103, for example, between dies 114-1, 114-2 and a circuit board 131.

The microelectronic assembly 100 may further include die 114-1 and die 114-2 electrically coupled to a top surface of the second substrate 148-2 by interconnects 150. In particular, conductive contacts 122 on a bottom surface of die 114-1, 114-2 may be electrically and mechanically coupled to conductive contacts 174 at a top surface of the second substrate 148-2 by interconnects 150.

Interconnects 150 may enable electrical coupling between die 114-1 and die 114-2 through conductive pathways 196 in substrate 148-2. Interconnects 150 disclosed herein may take any suitable form. In some embodiments, a set of interconnects 150 may include solder 132 (e.g., solder bumps or balls that are subject to a thermal reflow to form the interconnects 150). Interconnects 150 that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of interconnects 150 may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression. In some embodiments, interconnects 150 disclosed herein may have a pitch between about 18 microns and 75 microns. Although FIG. 1 shows dies 114-1, 114-2 electrically coupled to substrate 148-2 by interconnects 150, dies 114-1, 114-2 may be electrically coupled by any suitable interconnects.

The die 114 disclosed herein may include an insulating material (e.g., a dielectric material formed in multiple layers, as known in the art) and multiple conductive pathways formed through the insulating material. In some embodiments, the insulating material of a die 114 may include a dielectric material, such as silicon dioxide, silicon nitride, oxynitride, polyimide materials, glass reinforced epoxy matrix materials, or a low-k or ultra low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, the insulating material of a die 114 may include a semiconductor material, such as silicon, germanium, or a III-V material (e.g., gallium nitride), and one or more additional materials. For example, an insulating material may include silicon oxide or silicon nitride. The conductive pathways in a die 114 may include conductive traces and/or conductive vias, and may connect any of the conductive contacts in the die 114 in any suitable manner (e.g., connecting multiple conductive contacts on a same surface or on different surfaces of the die 114). The conductive pathways in the dies 114 may be bordered by liner materials, such as adhesion liners and/or barrier liners, as suitable. In some embodiments, the die 114 is a wafer. In some embodiments, the die 114 is a monolithic silicon, a fan-out or fan-in package die, or a die stack (e.g., wafer stacked, die stacked, or multi-layer die stacked). In various embodiments, die 114 may include, or be a part of, one or more of a central processing unit (CPU), a memory device (e.g., a high-bandwidth memory device), a logic circuit, input/output circuitry, a transceiver such as a field programmable gate array transceiver, a gate array logic such as a field programmable gate array logic, of a power delivery circuitry, a III-V or a III-N device such as a III-N or III-N amplifier (e.g., GaN amplifier), Peripheral Component Interconnect Express (PCIe) circuitry, Double Data Rate (DDR) transfer circuitry, or other electronic components known in the art. In some embodiments, die 114-1 and die 114-2 may include different functionalities. As used herein, the term “functionality” with reference to a die refers to one or more functions (e.g., capability, task, operation, action, instruction execution, etc.) that the die in question can perform. For example, die 114-1 may be a CPU and die 114-2 may be a Graphics Processing Unit (GPU) or memory. In other embodiments, die 114-1 and die 114-2 may include the same or similar functionalities. For example, die 114-1 and die 114-2 may each include memory.

The microelectronic assembly 100 of FIG. 1 may also include a bridge die 202. A bridge die 202 may be at least partially within a dielectric material of the second substrate 148-2 (e.g., at least partially nested in a cavity). The bridge die 202 may be electrically coupled to dies 114 (e.g., die 114-1 and die 114-2) by interconnects 150. In particular, conductive contacts 122 on the bottom surface of dies 114 may be electrically and mechanically coupled to the conductive contacts 124 on the top surface of the bridge die 202 by interconnects 150. A bridge die 202 may be electrically coupled to conductive pathways 196 in the second substrate 148-2 by interconnects 120. In some embodiments, as shown, interconnects 120 may include solder. A bridge die 202 may comprise appropriate circuitry on/in a semiconductor substrate to connect at silicon-interconnect speeds with a small footprint. In some embodiments, bridge die 202 may comprise active components, such as transistors and diodes in addition to bridge circuitry including metallization traces, vias and passive components for enabling electrical coupling between two ICs; in other embodiments, bridge die 202 may include bridge circuitry including metallization traces, vias and passive components for enabling electrical coupling between die 114-1 and die 114-2, and may not include active components. In some embodiments, a bridge die 202 may be omitted.

The microelectronic assembly 100 of FIG. 1 may also include an insulating material 135 that encapsulates the die 114 (e.g., on and around die 114 and interconnects 150). The insulating material 135 may extend from a top surface of the second substrate 148-2 to a top surface of the die 114. In some embodiments, the insulating material 135 may be a mold material, such as an organic polymer with inorganic silicon oxide or aluminum oxide particles, a resin material, or an epoxy material. In some embodiments (not shown) other components, such as heat sinks may be coupled to microelectronic assembly 100 based on particular needs.

The microelectronic assembly 100 of FIG. 1 may also include an underfill material 127. In some embodiments, the underfill material 127 may extend between die 114-1, 114-2 and the second substrate 148-2 around the associated interconnects 150. In some embodiments, the underfill material 127 may be between the bottom surface of the bridge die 202 and the second substrate 148-2 (not shown). The underfill material 127 may be an insulating material, such as an appropriate epoxy material. In some embodiments, the underfill material 127 may include a capillary underfill, non-conductive film (NCF), or molded underfill. In some embodiments, the underfill material 127 may include an epoxy flux that assists with soldering die 114-1, 114-2 to the second substrate 148-2 when forming the interconnects 150, and then polymerizes and encapsulates the interconnects 150. The underfill process may include dispensing underfill material in liquid form, allowing the material to flow and fill the interstitial gaps around interconnects 150, and subjecting the assembly to a curing process, such as baking, to solidify the material. In some embodiments, an underfill material 127 may be omitted. Although FIG. 1 shows two separate underfill 127 portions under die 114-1 and die 114-2, the underfill 127 may be a single underfill 127 under die 114-1 and die 114-2. The underfill material 127 may be selected to have a coefficient of thermal expansion (CTE) that may mitigate or minimize the stress between die 114 and the second substrate 148-2 arising from uneven thermal expansion in the microelectronic assembly 100. In some embodiments, the CTE of the underfill material 127 may have a value that is intermediate to the CTE of the second substrate 148-2 (e.g., the CTE of the dielectric material of the substrate 148) and a CTE of the insulating material of die 114.

The microelectronic assembly 100 of FIG. 1 may also include a circuit board 131. In particular, conductive contacts 172 on a bottom surface of the first substrate 148-1 may be electrically coupled to conductive contacts 146 on a top surface of circuit board 131 by interconnects 190. Interconnects 190 disclosed herein may take any suitable form, including solder balls for a ball grid array arrangement, pins in a pin grid array arrangement or lands in a land grid array arrangement, or any of the forms described above with reference to interconnects 150. As shown in FIG. 1, in some embodiments, a set of interconnects 190 may include solder 136 (e.g., solder bumps or balls that are subject to a thermal reflow to form the interconnects 190). In some embodiments, the interconnects 190 disclosed herein may have a pitch between about 50 microns and 300 microns. In some embodiments, an underfill material 127 may extend between the first substrate 148-1 and the circuit board 131 around the associated interconnects 190. The circuit board 131 may be a motherboard, for example, and may have other components attached to it. The circuit board may include conductive pathways and other conductive contacts for routing power, ground, and signals through the circuit board, as known in the art. In some embodiments, the interconnects 190 may not couple to a circuit board 131, but may instead couple to another IC package, an interposer, or any other suitable component.

In some embodiments, one or more levels of solder resist (e.g., epoxy liquid, liquid photoimageable dielectrics, dry film photoimageable dielectrics, acrylics, solvents) may be provided in an IC package described herein and may not be labeled or shown to avoid cluttering the drawings. Solder resist may be a liquid or dry film material including photoimageable dielectrics. In some embodiments, solder resist may be non-photoimageable.

Any suitable techniques may be used to manufacture the microelectronic assemblies 100 disclosed herein. For example, FIGS. 2A-2E are side, cross-sectional views of various stages in an example process for manufacturing the microelectronic assembly 100 of FIG. 1 prior to performing edge coating techniques, in accordance with various embodiments. Although the operations discussed below with reference to FIGS. 2A-2E (and others of the accompanying drawings representing manufacturing processes) are illustrated in a particular order, these operations may be performed in any suitable order. Further, additional operations which are not illustrated may also be performed without departing from the scope of the present disclosure. Also, various ones of the operations discussed herein with respect to FIGS. 2A-2E may be modified in accordance with the present disclosure to fabricate others of microelectronic assembly 100 disclosed herein.

FIG. 2A illustrates an assembly including a glass core 103 having a first surface 170-1 and a second surface 170-2, and TGVs 110. The glass core 103 may have any suitable dimensions, for example, the glass core 103 may include a full panel glass core having a surface area of approximately 500 millimeters by 500 millimeters (e.g., xy-dimension), or may include a quarter panel glass core having a surface area of approximately 250 millimeters by 250 millimeters. In some embodiments, a glass core 103 may have a surface area of between approximately 10 millimeters by 10 millimeters and approximately 240 millimeters by 240 millimeters.

FIG. 2B illustrates an assembly subsequent to forming substrates 148-1, 148-2 on respective surfaces 170-1, 170-2 of the glass core 103, including forming conductive pathways 196 and embedding bridge die 202 in the second substrate 148-2 (not shown so as to not overly complicate the figures). In some embodiments, further operations may be performed as well, including, for example, attaching dies 114-1, 114-2 to a top surface of the second substrate 148-2 by forming interconnects 150, depositing an underfill material 127, and depositing an insulating material 135 on and around the dies 114-1, 114-2. The assembly of FIG. 2B may be manufactured using conventional package substrate manufacturing techniques. The dielectric of the substrate 148 may be deposited using any suitable technique, including lamination, and may be removed using any suitable technique, such as laser patterning or lithography, to form a cavity for placing a bridge die 202 therein. In some embodiments, bridge die 202 may be omitted. The conductive pathways 196 may be any suitable conductive material, such as copper, silver, nickel, gold, aluminum, or other metals or alloys, and may be deposited using any suitable process, including lithography, electrolytic plating, or electroless plating.

FIG. 2C illustrates an assembly subsequent to singulating 213 through a dielectric material of the substrates 148-1, 148-2 to expose the first and second surfaces 170-1, 170-2 of the glass core 103. The dielectric material of the substrates 148-1, 148-2 may be removed using any suitable technique, such as routing, sawing or laser drilling.

FIG. 2D illustrates an assembly subsequent to singulating 215 through the glass core 103. The material of the glass core 103 may be removed using any suitable process, including IR laser perforation. The singulation process may mechanically compromise and weaken the glass core 103 at a region 139 adjacent to where the singulation occurred. Singulation may be performed on all edges (e.g., at all four sides) of the substrates 148-1, 148-2 and the glass core 103. A region 139 along the edges 170-3 of the glass core 103 may be more susceptible to cracks and fracture post-singulation.

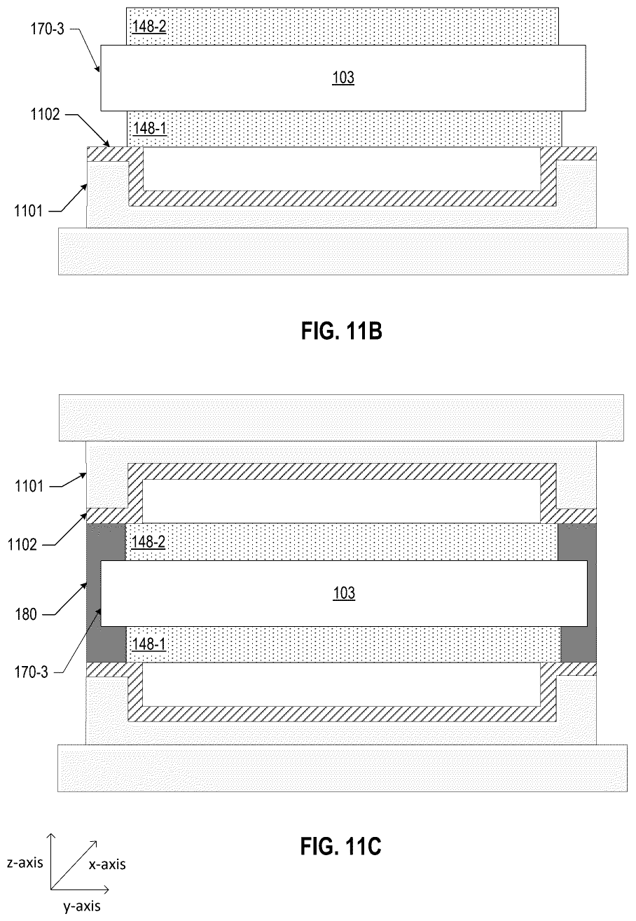

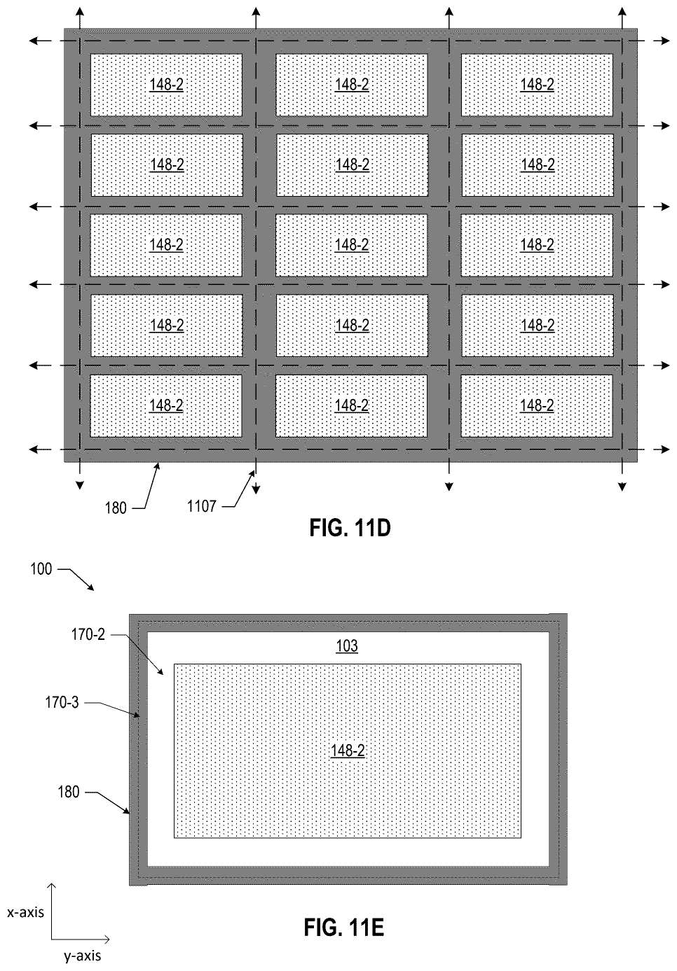

FIG. 2E illustrates an assembly subsequent to providing an edge protection coating 180 on an edge 170-3 of the glass core 103. The edge protection coating 180 may have any suitable profile, including, as shown in FIG. 2E and in FIGS. 4-16. The edge protection coating 180 may be deposited using any suitable technique, for example, lithography, coating and patterning with a laser, or any of the techniques described below with reference to FIGS. 4-16. In some embodiments, as described below with reference to FIG. 11, an edge protection coating 180 may be provided prior to singulation.

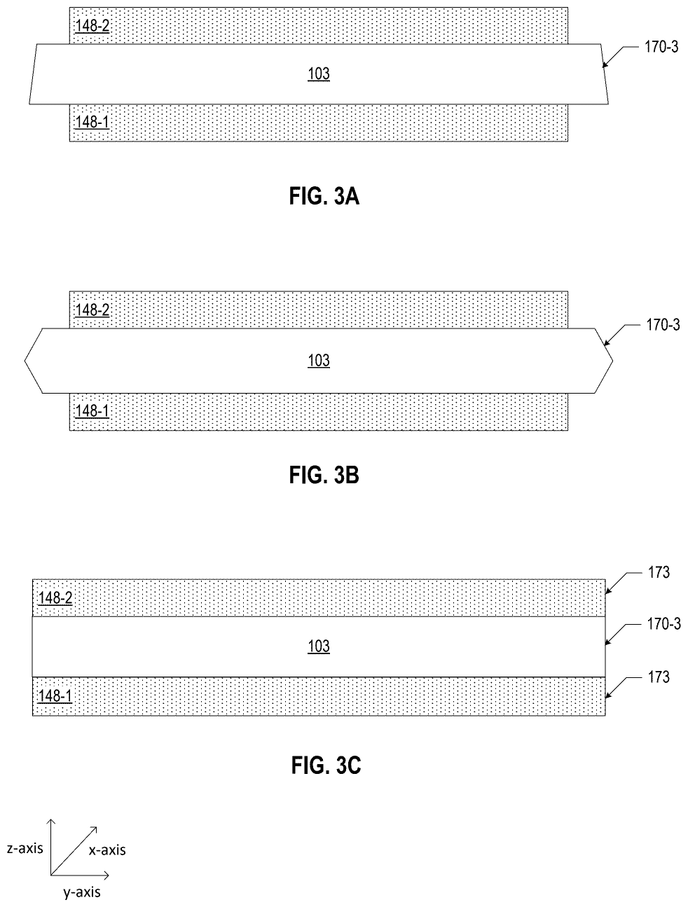

A glass core 103 may include edges 170-3 having any suitable profile, as described with reference to FIGS. 3A-3C. A profile of an edge 170-3 may be determined based on the singulation process used. FIG. 3A is a simplified schematic cross-sectional view of an example microelectronic assembly 100 of FIG. 1 according to some embodiments of the present disclosure. For example, as shown in FIG. 3A, a glass core 103 may include an edge 170-3 (e.g., defined by the xz-dimension) that is sloped or angled. An edge 170-3 having a sloped profile, as shown in FIG. 3A, may be formed by performing IR laser perforation at a second surface 170-2 of the glass core 103. An edge 170-3 having an inverted sloped profile (e.g., wider towards the second surface 170-2 and narrower towards the first surface 170-1) may be formed by performing IR laser perforation at a first surface 170-1 of the glass core 103.

FIG. 3B is a simplified schematic cross-sectional view of an example microelectronic assembly 100 of FIG. 1 according to some embodiments of the present disclosure. For example, as shown in FIG. 3B, a glass core 103 may include an edge 170-3 that protrudes in a middle of the glass core 103. Put another way, the edge 170-3 includes two sloping portions that taper out towards a middle of the glass core 103. An edge 170-3 having two sloping portions, as shown in FIG. 3B, may be formed by performing IR laser perforation at both the first and second surfaces 170-1, 170-2 of the glass core 103.

FIG. 3C is a simplified schematic cross-sectional view of an example microelectronic assembly 100 of FIG. 1 according to some embodiments of the present disclosure. For example, as shown in FIG. 3C, a glass core 103 may include an edge 170-3 that is substantially straight and co-planar with a respective lateral surface 173 of the first and second substrates 148-1, 148-2. An edge 170-3 having a straight profile that is aligned with a lateral surface 173 of a first and second substrates 148-1, 148-2, as shown in FIG. 3C, may be formed by a saw process which ensures the edges are flush. Although FIGS. 3A-3C illustrate the substrates 148-1, 148-2 having straight lateral surfaces (e.g., lateral surfaces 173, as shown in FIG. 1), the substrates 148-1, 148-2 may have lateral surfaces with any suitable profile, including profiles similar to the edge profiles described above with reference to the edge 170-3 in FIGS. 3A-3C.

FIG. 4 shows a schematic cross-sectional view of a portion of another example microelectronic assembly 100 according to some embodiments of the present disclosure. The configuration of the embodiment shown in the figure is like that of FIG. 1, except for differences as described further. In particular, FIG. 4 illustrates an embodiment where an edge protection coating 180 is provided on an edge 170-3 and on a portion of first and second surfaces 170-1, 170-2 of the glass core 103 having a foam-like and/or disordered, tortuous profile. A material of the edge protection coating 180 may include a polymeric foam, such as a low-density polystyrene or polycarbonate foam. The edge protection coating 180 may be applied using any suitable technique, such as a spray foam dispense nozzle, and then dried or cured. The thickness of the foam can be between 5 and 500 microns. In some embodiments, a polymeric foam may be applied using a lithography process and may form an edge protection coating that may be patterned along the edge 170-3 of the core 103, for example, as shown in FIG. 1.

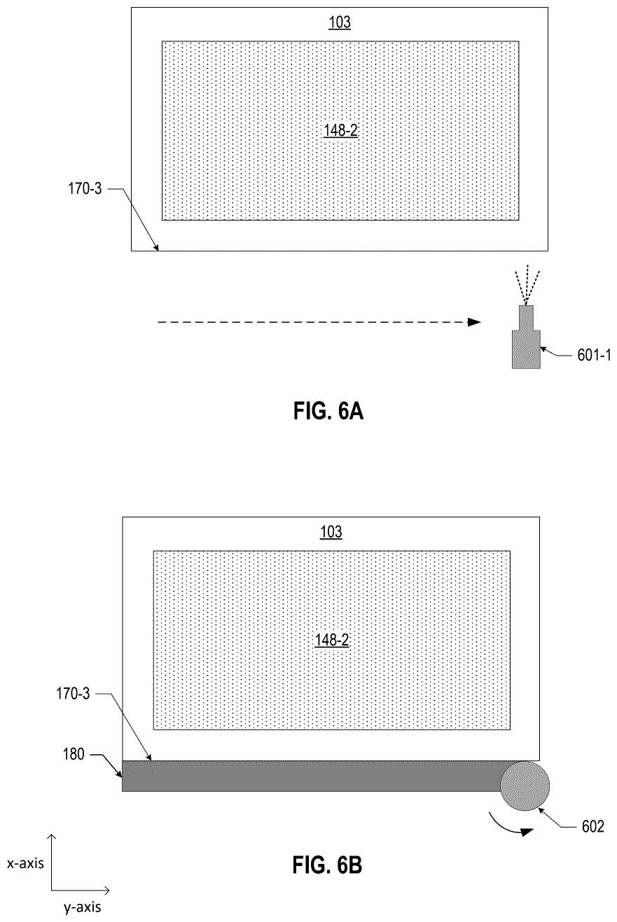

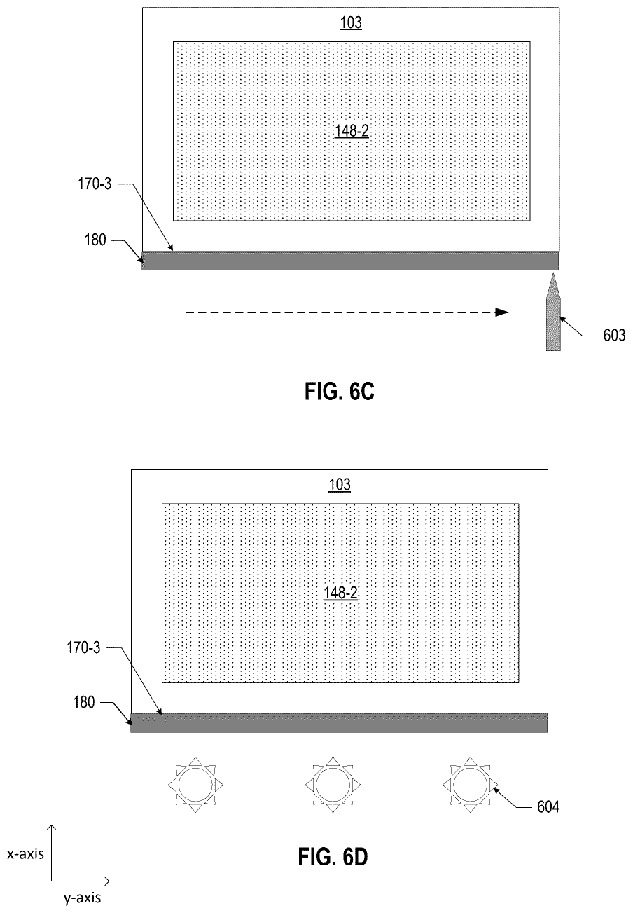

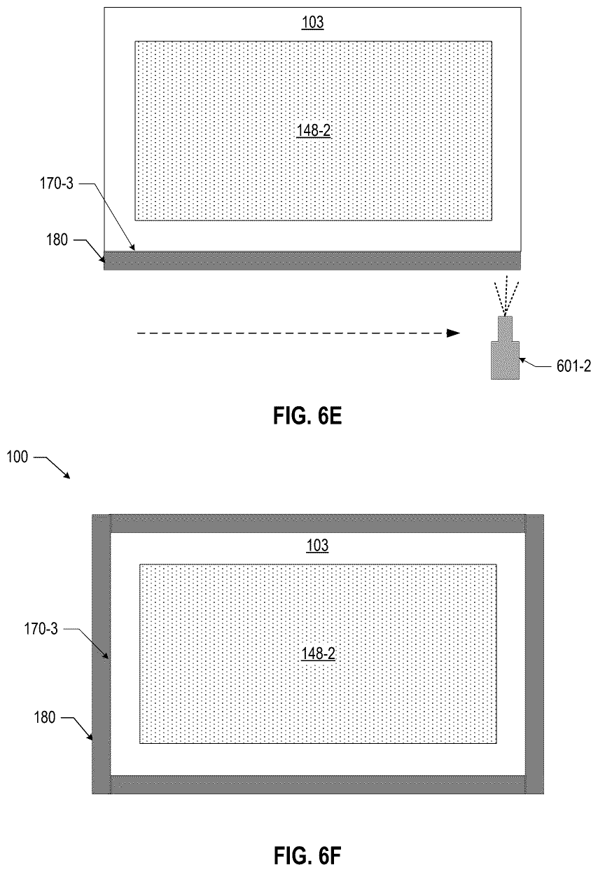

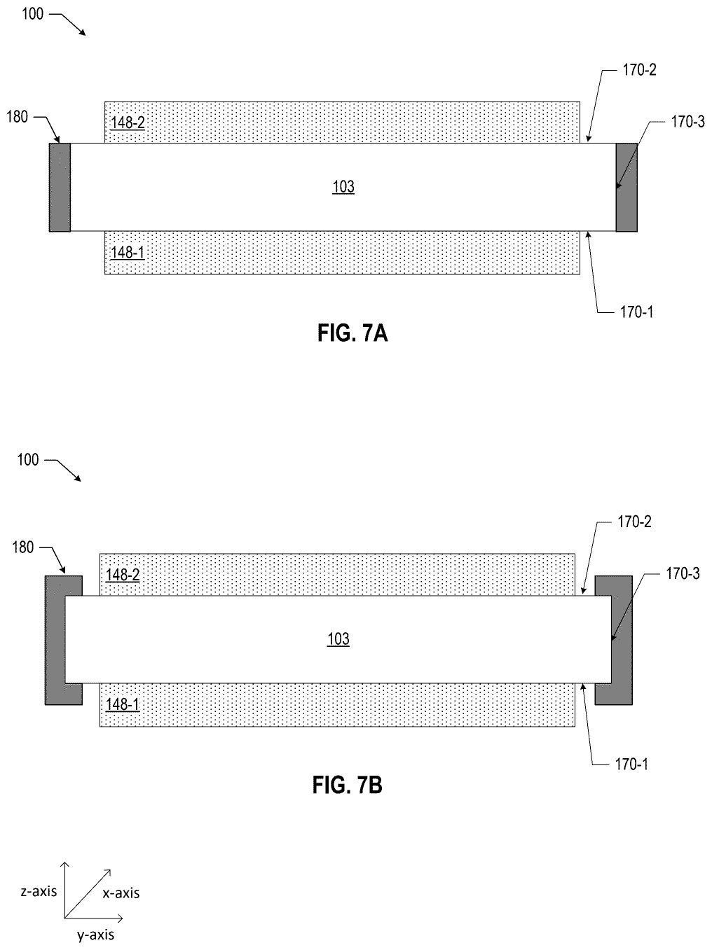

FIG. 5 shows a schematic cross-sectional view of a portion of another example microelectronic assembly 100 according to some embodiments of the present disclosure. The configuration of the embodiment shown in the figure is like that of FIG. 1, except for differences as described further. The configuration of microelectronic assembly 100 is as described herein except that the edge protection coating 180 has a rounded or dome-shaped profile. Such an embodiment may be advantageous in terms of reducing stress concentration zones in the glass core 103, compared to a straight edge (e.g., as shown in FIG. 7A), and, thereby, reducing the susceptibility of the glass core 103 to crack formation and propagation. In some embodiments, the rounded or dome-shaped edge protection coating 180 may be realized using a roller coating process (e.g., as described below with reference to FIGS. 6A-6F) and may be attributed to the surface tension of the material of the edge protection coating 180. Example materials of an edge protection coating 180 that may be applied using a roller coating process, as shown in FIG. 5, may include, but is not limited to, a fiber reinforced resin, a pre-impregnated dielectric, a pre-impregnated fabric, or a CNT reinforced epoxy resin.

FIGS. 6A-6F are top views of various stages in an example process for manufacturing the edge protection coating 180 of microelectronic assembly 100 of FIG. 5, in accordance with various embodiments. Although the operations discussed below with reference to FIGS. 6A-6F (and others of the accompanying drawings representing manufacturing processes) are illustrated in a particular order, these operations may be performed in any suitable order. Further, additional operations which are not illustrated may also be performed without departing from the scope of the present disclosure. Also, various ones of the operations discussed herein with respect to FIGS. 6A-6F may be modified in accordance with the present disclosure.

FIG. 6A illustrates a schematic top view of an assembly including a glass core 103, a substrate 148-2, and an edge 170-3 subsequent to the edge 170-3 undergoing a first visual inspection 601-1 to determine a profile of the edge 170-3. The first visual inspection 601-1 may map the profile of the edge 170-3 (e.g., to determine a profile of the edge 170-3, for example, as shown in FIGS. 1 and 3A-3C). Although FIG. 6 illustrates the edge 170-3 of the glass core 103 as extending beyond the substrate 148-2, in some embodiments, the edge 170-3 of the glass core 103 is flush with the substrate 148-2, for example, as shown in FIG. 3C.

FIG. 6B illustrates an assembly subsequent to roller coating 602 an edge protection coating 180 on the edge 170-3.

FIG. 6C illustrates an assembly subsequent to scraping 603 to remove excess material of the edge protection coating 180 on the edge 170-3.

FIG. 6D illustrates an assembly subsequent to curing 604 the material of the edge protection coating 180 using any suitable technique, such as an ultraviolet (UV) light.

FIG. 6E illustrates an assembly subsequent to the edge 170-3 undergoing a second visual inspection 601-2 to determine whether the edge protection coating 180 is coated completely and without significant defects.

FIG. 6F illustrates an assembly subsequent to the edge protection coating 180 being coated, scraped, cured, and inspected, as described above with reference to FIGS. 6A-6E, for each edge 170-3 of the assembly.

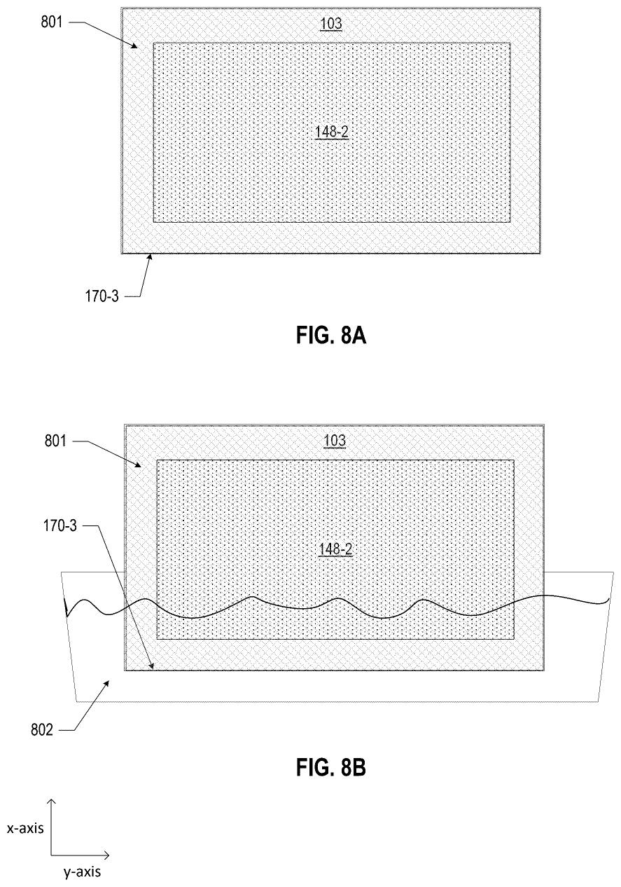

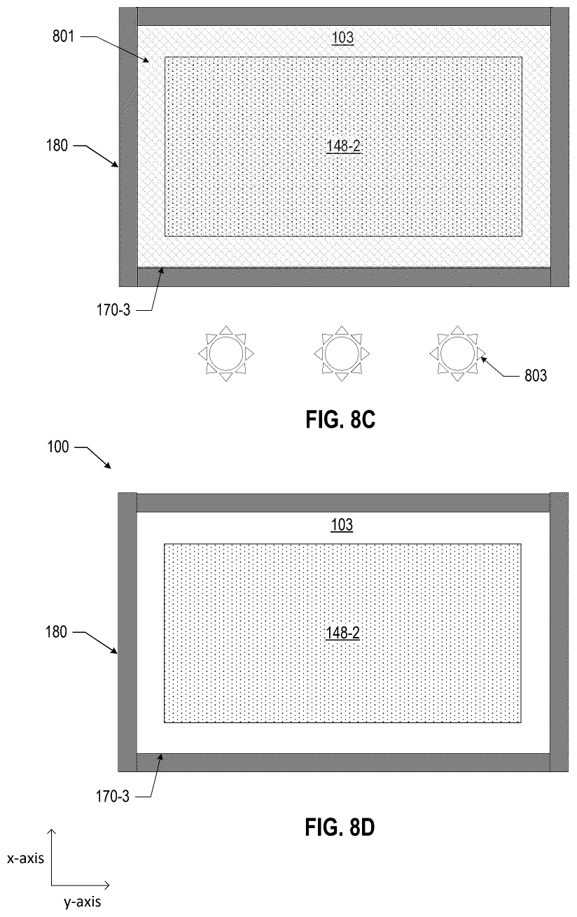

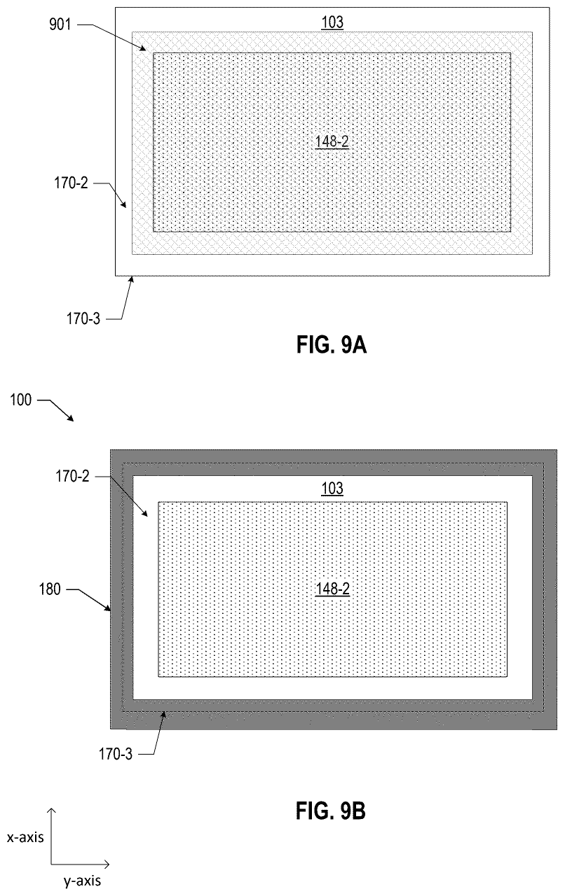

FIGS. 7A and 7B show schematic cross-sectional views of portions of other example microelectronic assemblies 100 according to some embodiments of the present disclosure. The configurations of the embodiments shown in the figures are like that of FIG. 1, except for differences as described further. The configuration of microelectronic assembly 100 shown in FIG. 7A is as described herein except that the edge protection coating 180 along an edge 170-3 has a rectilinear profile with substantially straight and perpendicular sides (e.g., as also shown in FIGS. 1 and 2E) along the edge 170-3. The configuration of microelectronic assembly 100 shown in FIG. 7B is like that of FIG. 7A except that the edge protection coating 180 is along an edge 170-3 and further extends on at least a portion of the first and second surfaces 170-1, 170-2 of the glass core 103. In some embodiments, the edge protection coating 180 on the edge 170-3 (e.g., as shown in FIG. 7A), and the edge protection coating 180 on the edge 170-3 and extending on at least a portion of the first and second surfaces 170-1, 170-2 (e.g., as shown in FIG. 7B) may be realized using a dip coating process (e.g., as described below with reference to FIGS. 8A-8D and FIGS. 9A and 9B, respectively). An example material of the edge protection coating 180 deposited using a dip coating process may include an ionogel, such as a deep eutectic ionogel or a synthetic ionogel having a relatively high Young's modulus (e.g., between 15-200 gigapascals (GPa), where the Young's modulus may be defined as the ratio of stress to strain in a material undergoing deformation).

FIGS. 8A-8D and FIGS. 9A and 9B are top views of various stages in an example process for manufacturing the edge protection coating 180 of microelectronic assembly 100 of FIGS. 7A and 7B, respectively, in accordance with various embodiments.

FIG. 8A illustrates a schematic top view of an assembly including a glass core 103, a first substrate 148-1 (not shown), a second substrate 148-2, and an edge 170-3 subsequent to depositing a hard mask 801 on the first and second substrates 148-1, 148-2 and on the first and second surfaces 170-1, 170-2 of the glass core 103. The hard mask 801 may include any suitable mask, including a metal layer, such as nickel, tin, or copper, that may be deposited to prevent the masked areas from being exposed during the dip coating process. Although FIG. 8 illustrates the edge 170-3 of the glass core 103 as extending beyond the substrate 148-2, in some embodiments, the edge 170-3 of the glass core 103 is flush with the substrate 148-2, for example, as shown in FIG. 3C.

FIG. 8B illustrates an assembly subsequent to submerging an edge 170-3 of the assembly of FIG. 8A in an edge protection coating solvent 802 for a period of time, for example, between 5 minutes and 15 minutes. Although FIG. 8B illustrates a single edge 170-3 being submerged at a time. In some embodiments, the entire assembly may be submerged.

FIG. 8C illustrates an assembly subsequent to submerging all edges 170-3 in the edge protection coating solvent 802 and exposing the assembly to photo-polymerization 803 (e.g., UV light) forming an edge protection coating 180 along the edge 170-3 by polymerizing and curing the edge protection coating solvent 802.

FIG. 8D illustrates an assembly subsequent to removing the hard mask 801 from the assembly of FIG. 8C. The hard mask 801 may be removed using any suitable technique, including selective etching.

FIG. 9A illustrates a schematic top view of an assembly including a glass core 103, a first substrate 148-1 (not shown), a second substrate 148-2, and an edge 170-3 subsequent to depositing a hard mask 901 on the first and second substrates 148-1, 148-2 and on the first and second surfaces 170-1, 170-2 of the glass core 103, where a portion of the first and second surfaces 170-1, 170-2 are exposed along a perimeter of the glass core 103. The hard mask 901 may include any suitable mask, such as described above with reference to FIG. 8A.

FIG. 9B illustrates an assembly subsequent to forming an edge protection coating 180 along an edge 170-3 and on a portion of the first and second surfaces 170-1, 170-2 of the glass core 103. The assembly of FIG. 9B may be formed by submerging the assembly of FIG. 9A in an edge protection coating solution, exposing the assembly to photo-polymerization, and removing the hard mask as described above with reference to FIGS. 8B-8D.

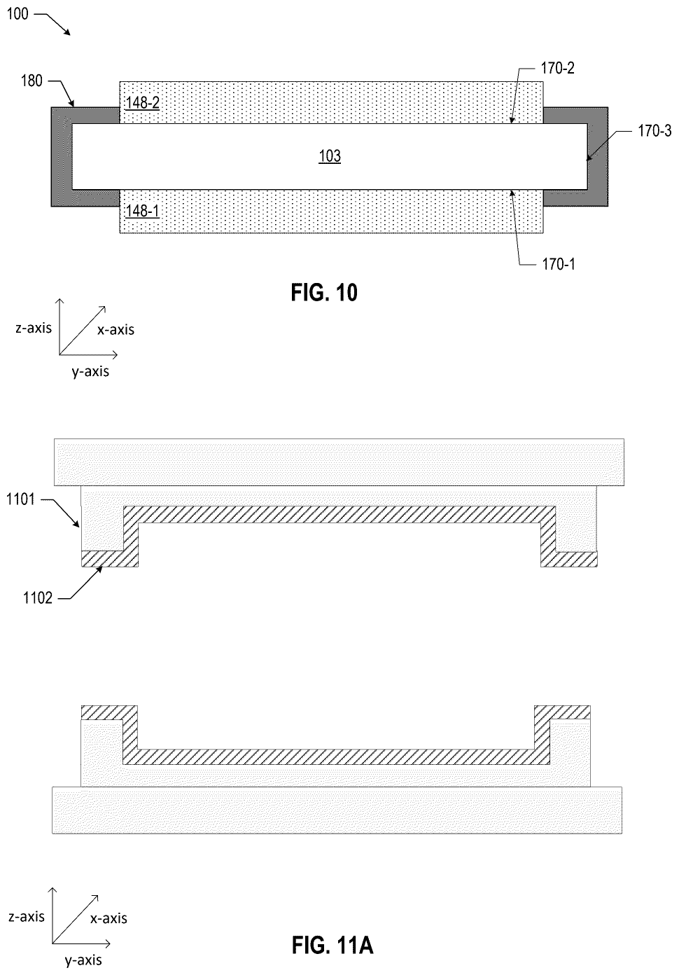

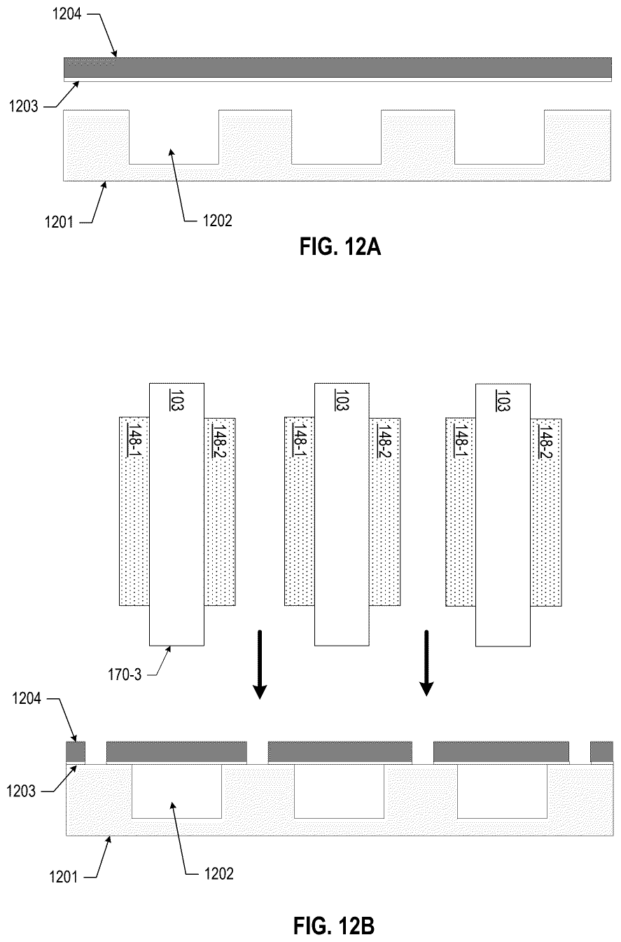

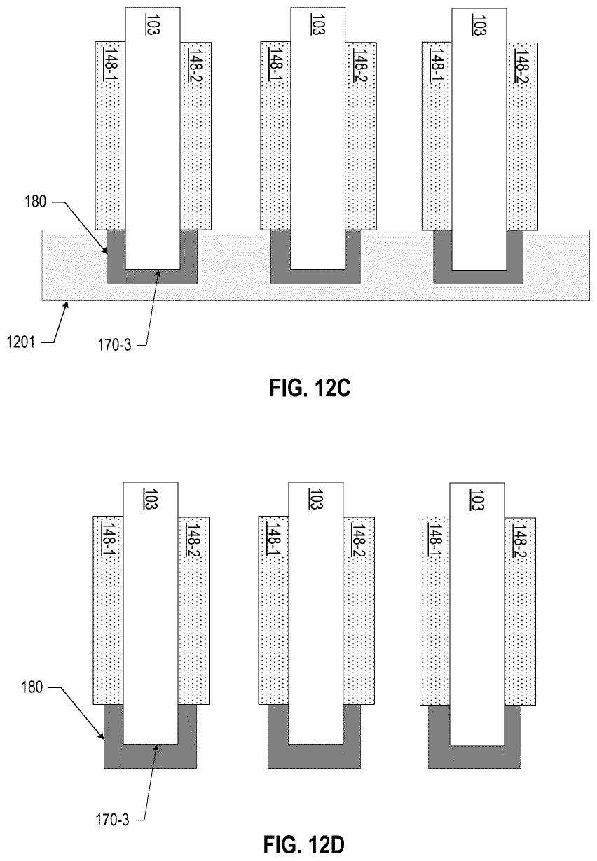

FIG. 10 shows a schematic cross-sectional view of a portion of another example microelectronic assembly 100 according to some embodiments of the present disclosure. The configuration of the embodiment shown in the figure is like that of FIG. 1, except for differences as described further. The configuration of microelectronic assembly 100 is as described herein except that the edge protection coating 180 is along an edge 170-3 and further extends on at least a portion of the first and second surfaces 170-1, 170-2 of the glass core 103. In some embodiments, the C-shaped edge protection coating 180 may be realized using an edge molding process (e.g., as described below with reference to FIGS. 11A-11E and FIG. 12A-12D). Example materials of an edge protection coating 180 that may be applied using an edge molding process, as shown in FIG. 10, may include a fiber reinforced resin, a pre-impregnated dielectric, a pre-impregnated fabric, or a CNT reinforced epoxy resin.

FIGS. 11A-11E and FIGS. 12A-12D are side/top views of various stages in an example process for manufacturing the edge protection coating 180 of microelectronic assembly 100 of FIG. 10 in accordance with various embodiments.

FIG. 11A illustrates a schematic side view of a mold machine 1101 having top and bottom portions subsequent to depositing a release film 1102 on surfaces of the mold machine 1101. The release film 1102 may be deposited using any suitable technique, including lamination.

FIG. 11B illustrates an assembly including a glass core 103, a first substrate 148-1 at a first surface 170-1, a second substrate 148-2 at a second surface 170-2, and an edge 170-3 subsequent to placing in a bottom portion of the mold machine 1101 of FIG. 11A. The assembly may be placed using, for example, a pick and place machine.

FIG. 11C illustrates the assembly subsequent to placing a top portion of the mold machine 1101 on the bottom portion, closing the mold machine 1101, and injecting a material for an edge protection coating 180 in the gaps at an edge 170-3 of the glass core 103. In some embodiments, a mold machine 1101 may house a plurality of assemblies within a frame and the material may be dispensed within the frame around each of the plurality of assemblies.

FIG. 11D illustrates a schematic top view of a plurality of assemblies subsequent to demolding from the mold machine 1101 and prior to singulation, where the assemblies are surrounded by an edge protection coating 180. FIG. 11D further illustrates singulation streets 1107 for singulating the plurality of assemblies into individual assemblies. The plurality of assemblies may be singulated using any suitable technique, including IR laser perforation.

FIG. 11E illustrates a schematic top view of an assembly subsequent to singulation having an edge protection coating 180 along an edge 170-3 and on a portion of the first and second surfaces 170-1 (not shown), 170-2 of the glass core 103, as shown in FIG. 10.

FIG. 12A illustrates a schematic side view of a mold machine 1201 with a plurality of slots 1202, and a material 1204 for forming an edge protection coating laminated to a substrate 1203 and aligned with a top surface of the mold machine 1201.

FIG. 12B illustrates a mold machine 1201 subsequent to attaching the substrate 1203 with the material 1204 for forming an edge protection coating 180 to the top surface of the mold machine 1201, cutting (e.g., using a laser) the substrate 1203 and the material 1204 between the slots 1202, and aligning an assembly including a glass core 103, a first substrate 148-1 at a first surface 170-1, a second substrate 148-2 at a second surface 170-2, and an edge 170-3 with each slot 1202.

FIG. 12C illustrates a mold machine 1201 subsequent to pressing the assemblies into the slots 1202 and performing a pre-curing process, such as a thermal pre-curing process, to form an edge protection coating 180 along an edge 170-3 and on a portion of the first and second surfaces 170-1, 170-2 of the glass core 103.

FIG. 12D illustrates a schematic side view of a plurality of assemblies subsequent to demolding from the mold machine 1201 and performing a final curing process, where an edge 170-3 of the assemblies include an edge protection coating 180 having a C-shape, as shown in FIG. 10. The processes described in FIGS. 12A-12D may be repeated for each edge 170-3 of the glass core 103 of the assemblies.

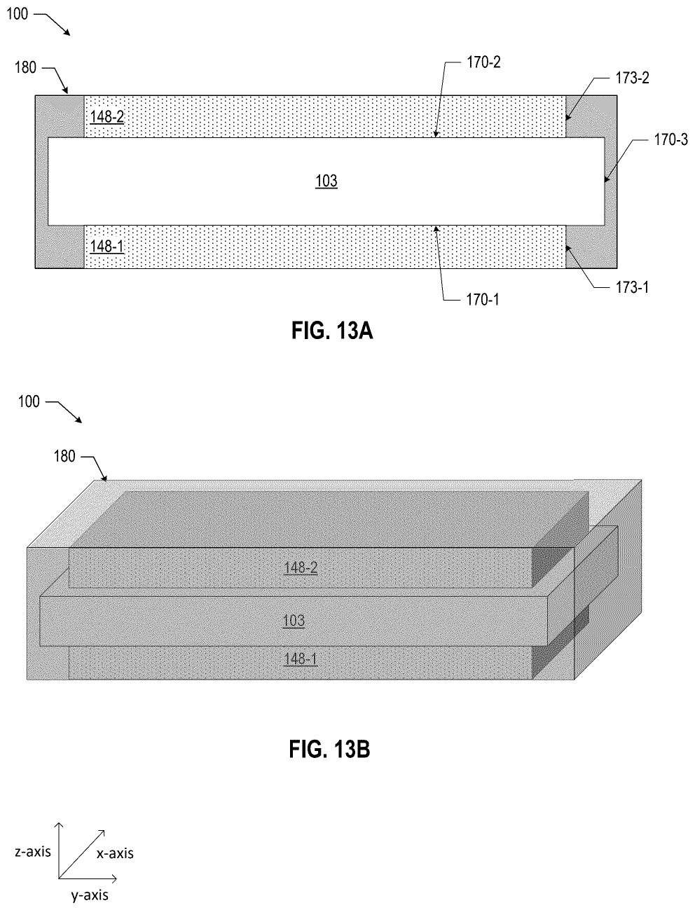

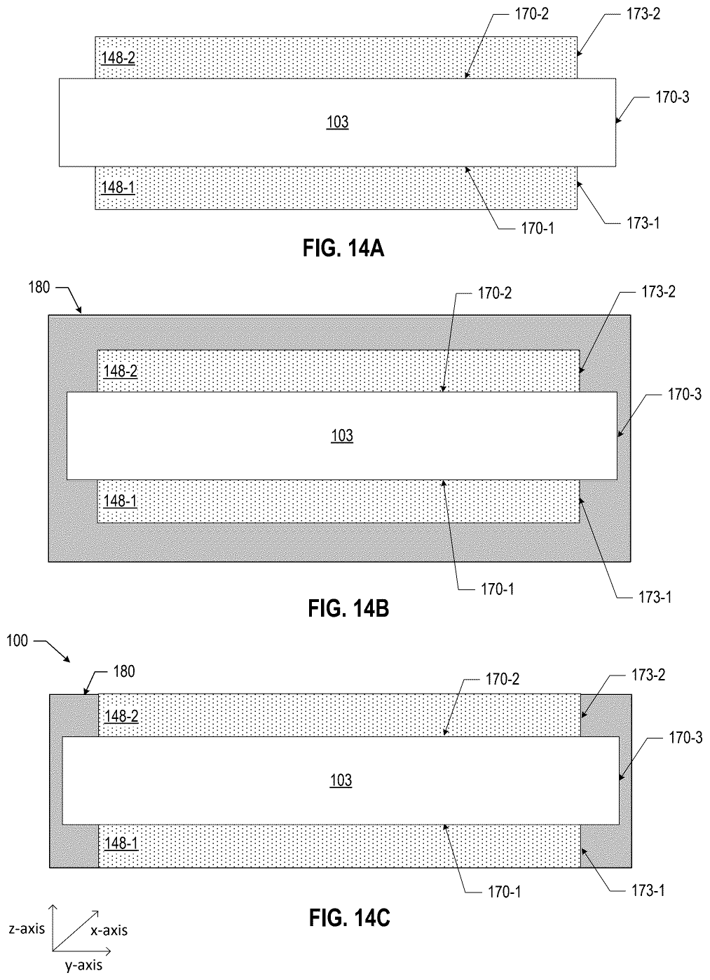

FIG. 13A shows a schematic cross-sectional view of a portion of another example microelectronic assembly 100 and FIG. 13B is a perspective view of the example microelectronic assembly 100 of FIG. 13A according to some embodiments of the present disclosure. The configuration of the embodiments shown in the figures are like that of FIG. 10, except for differences as described further. The configuration of microelectronic assembly 100 is as described herein except that an edge protection coating 180 may extend to physically contact and fully cover lateral surfaces 173-1, 173-2 of the first and second substrates 148-1, 148-2, respectively. In some embodiments, the edge protection coating 180 of FIG. 13 may be realized using an overmolding process (e.g., as described below with reference to FIGS. 14A-14C). Example materials of an edge protection coating 180 that may be applied using an overmolding process, as shown in FIG. 13, may include a mold material or a solder resist. A mold material may include any suitable material, such as an organic polymer with inorganic silica particles. A solder resist may include a polymer material that is resistant to the heat of soldering.

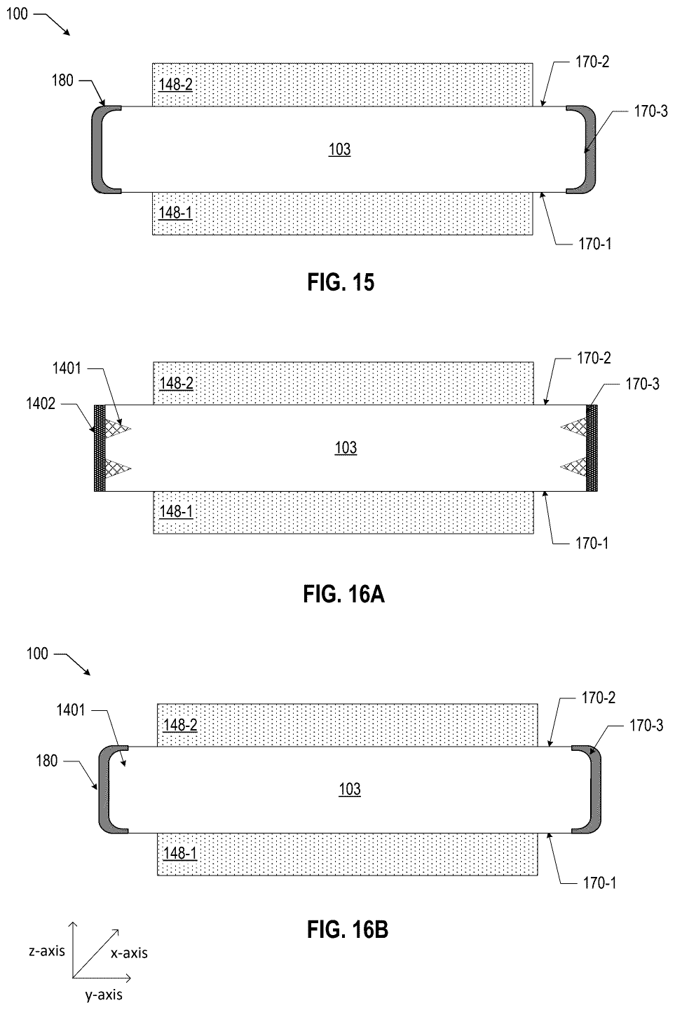

FIGS. 14A-14C are side views of various stages in an example process for manufacturing the edge protection coating 180 of microelectronic assembly 100 of FIG. 15 in accordance with various embodiments.

FIG. 14A illustrates an assembly including a glass core 103, a first substrate 148-1 at a first surface 170-1 of the glass core 103 having a lateral surface 173-1, a second substrate 148-2 at a second surface 170-2 of the glass core 103 having a lateral surface 173-2, and an edge 170-3.

FIG. 14B illustrates an assembly subsequent to depositing a material for an edge protection coating 180 on and around the assembly of FIG. 14A to encase the assembly. The material may be formed using any suitable process, including, for example, transfer molding, compression molding, lamination, or slit coating and curing.

FIG. 14C illustrates an assembly subsequent to polishing back a material of the edge protection coating 180 to expose bottom and top surfaces of the assembly (e.g., a dielectric material of the substrates 148-1, 148-2). The material may be removed using any suitable technique, including grinding, etching, chemical mechanical polishing (CMP), or skivving. In some embodiments, the thickness of the material may be minimized to reduce the etching time required.

FIG. 15 shows a schematic cross-sectional view of a portion of another example microelectronic assembly 100 according to some embodiments of the present disclosure. The configuration of the embodiment shown in the figure is like that of FIG. 1, except for differences as described further. The configuration of microelectronic assembly 100 is as described herein except that a material of the edge protection coating 180 includes a metal oxide and the edge 170-3 has undergone thermal and/or chemical treatment that may heal edge defects and cracks. In some embodiments, the edge protection coating 180 of FIG. 15 may be realized using a local heating process of a metal material at an edge 170-3 (e.g., as described below with reference to FIGS. 16A and 16B). As shown in FIG. 15, the edge 170-3 of the glass core 103 may have a rounded profile due to thermal exposure.

FIG. 16A illustrates an assembly an assembly including a glass core 103, a first substrate 148-1 at a first surface 170-1 of the glass core 103, a second substrate 148-2 at a second surface 170-2 of the glass core 103, and a metal material 1402 deposited on an edge 170-3 of the glass core 103, where the glass core 103 may include edge defects and/or cracks 1401. In some embodiments, the metal material 1402 may be deposited as a thin film along an edge 170-3 of the glass core 103 using any suitable technique, for example, radio frequency (RF) sputtering, plasma-enhanced chemical vapor deposition (PECVD), or plating. In some embodiments, the metal material 1402 may include any suitable reactive metal, such as aluminum (Al), magnesium (Mg), titanium (Ti), zinc (Zn), silicon (Si), boron (B), or lithium (Li) that may react with metal oxide components of the glass (e.g., SiO₂/B₂O₃) in the glass core 103 by heating to initiate a thermite reaction based on the equation M+SiO₂/B₂O₃=MOₓ+Si/B+ΔH, where M is a metal. In some embodiments, the metal material 1402 may include mixture of a reactive metal (e.g., Al, Li, etc.) and an oxidant (e.g., a metal oxide or polytetrafluoroethylene (PTFE)) that may react with each other and not with the components of the glass (e.g., SiO₂/B₂O₃) in the glass core 103 by heating to initiate a thermite reaction based on the equation MOₓ+Al/Li=M+Al₂O₃/Li₂O₃+ΔH, where M is a metal that is not Al or Li and MOₓ may include, for example, Fe₂O₃ or CuO, etc.

FIG. 16B illustrates an assembly subsequent to exposing the edges 170-3 of the glass core 103 with the metal material 1402 to localized heating to heal edge defects and cracks 1401 and to form an edge protection coating 180 including a metal oxide on the edge 170-3 of the glass core 103. The localized heating may be achieved using any suitable technique, such as fire polishing or laser polishing, to achieve the chemical reactions as described above with reference to FIG. 16A. In some embodiments, exothermic hypergolic reactions may be used to achieve a localized heating effect using the equation KMnO₄+glycerol/similar hydrocarbon=K⁺/Mn²⁺+CO₂+H₂O+ΔH.

The assemblies of FIGS. 2E, 4, 5, 6F, 7A, 7B, 8D, 9B, 10, 11E, 13A, 13B, 14C, 15, and 16B may themselves be microelectronic assemblies 100, as shown. Further manufacturing operations may be performed on the microelectronic assemblies 100 of FIGS. 2E, 4, 5, 6F, 7A, 7B, 8D, 9B, 10, 11E, 13A, 13B, 14C, 15, and 16B to form other microelectronic assemblies 100; for example, performing surface finishing operations, such as attaching dies 114 by forming interconnects 150 (e.g., if not previously attached), depositing solder resist, depositing solder 136 at a bottom surface of the first substrate 148-1, attaching a circuit board 131 to a bottom surface of the microelectronic assemblies 100 of FIGS. 2E, 4, 5, 6F, 7A, 7B, 8D, 9B, 10, 11E, 13A, 13B, 14C, 15, and 16B by forming interconnects 190, similar to FIG. 1.

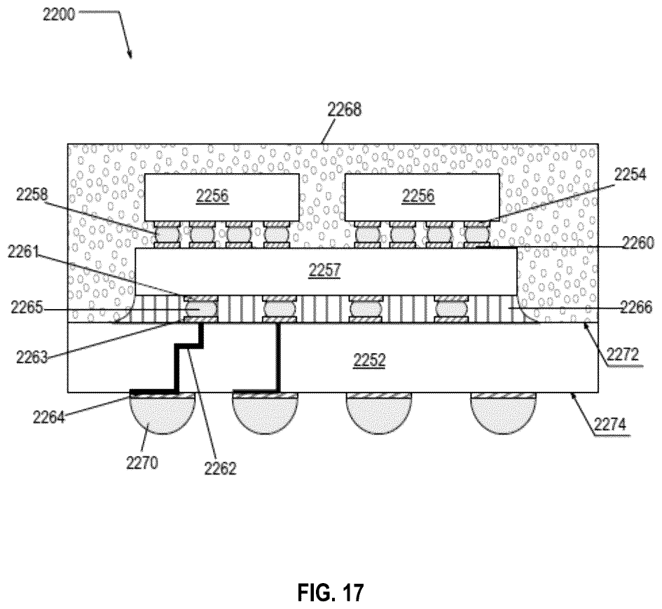

The packages disclosed herein, e.g., any of the microelectronic assemblies 100, or any further embodiments described herein, may be included in any suitable electronic component. FIGS. 17-19 illustrate various examples of packages, assemblies, and devices that may be used with or include any of the IC packages as disclosed herein.

FIG. 17 is a side, cross-sectional view of an example IC package 2200 that may include microelectronic assemblies in accordance with any of the embodiments disclosed herein. In some embodiments, the IC package 2200 may be a system-in-package (SiP).

As shown in FIG. 17, package support 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures including lines and/or vias, e.g., as discussed above with reference to FIG. 1.

Package support 2252 may include conductive contacts 2263 that are coupled to conductive pathway 2262 through package support 2252, allowing circuitry within dies 2256 and/or interposer 2257 to electrically couple to various ones of conductive contacts 2264 (or to other devices included in package support 2252, not shown).

IC package 2200 may include interposer 2257 coupled to package support 2252 via conductive contacts 2261 of interposer 2257, first level interconnects (FLI) 2265, and conductive contacts 2263 of package support 2252. FLI 2265 illustrated in FIG. 17 are solder bumps, but any suitable FLI 2265 may be used, such as solder bumps, solder posts, or bond wires.

IC package 2200 may include one or more dies 2256 coupled to interposer 2257 via conductive contacts 2254 of dies 2256, FLI 2258, and conductive contacts 2260 of interposer 2257. In various embodiments, interposer 2257 may include glass core 103 including glass as described herein. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). FLI 2258 illustrated in FIG. 17 are solder bumps, but any suitable FLI 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

In some embodiments, underfill material 2266 may be disposed between package support 2252 and interposer 2257 around FLI 2265, and mold 2268 may be disposed around dies 2256 and interposer 2257 and in contact with package support 2252. In some embodiments, underfill material 2266 may be the same as mold 2268. Example materials that may be used for underfill material 2266 and mold 2268 are epoxies as suitable. Second level interconnects (SLI) 2270 may be coupled to conductive contacts 2264. SLI 2270 illustrated in FIG. 17 are solder balls (e.g., for a ball grid array (BGA) arrangement), but any suitable SLI 2270 may be used (e.g., pins in a pin grid array arrangement or lands in a land grid array arrangement). SLI 2270 may be used to couple IC package 2200 to another component, such as a circuit board (e.g., a motherboard), an interposer, or another IC package, as known in the art and as discussed below with reference to FIG. 19.

In embodiments in which IC package 2200 includes multiple dies 2256, IC package 2200 may be referred to as a multichip package (MCP). Dies 2256 may include circuitry to perform any desired functionality. For example, besides one or more of dies 2256 including components of dies 114 as described herein, one or more of dies 2256 may be logic dies (e.g., silicon-based dies), one or more of dies 2256 may be memory dies (e.g., high-bandwidth memory), etc. In some embodiments, at least some of dies 2256 may not include components of dies 114 as described herein.

Although IC package 2200 illustrated in FIG. 17 is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package support 2252, or on either face of interposer 2257. More generally, IC package 2200 may include any other active or passive components known in the art.

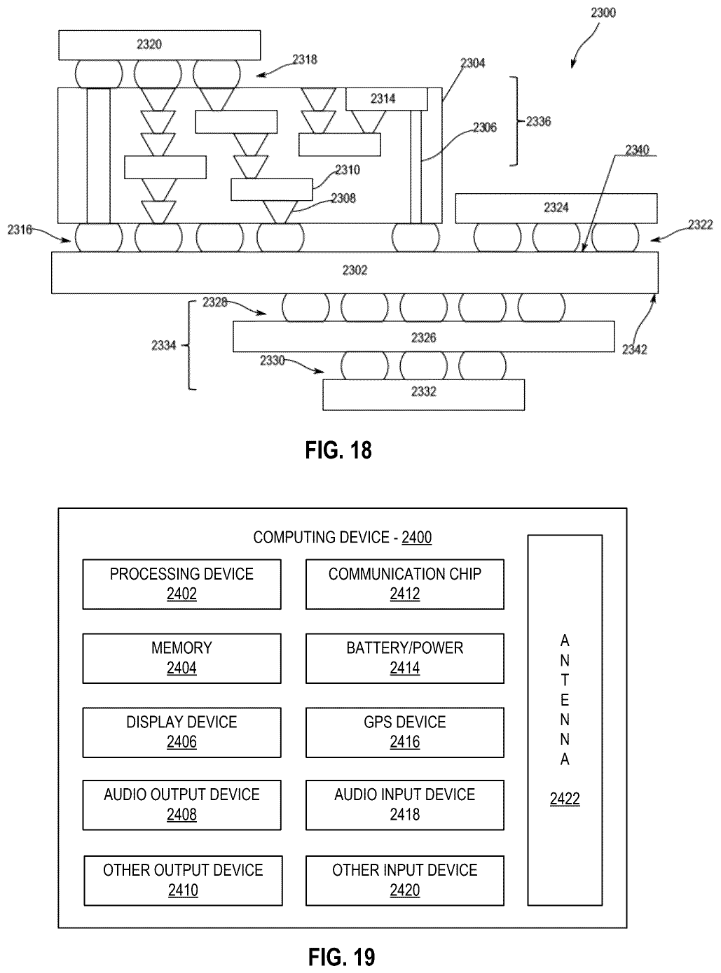

FIG. 18 is a cross-sectional side view of an IC device assembly 2300 that may include components having one or more microelectronic assembly 100 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 100 in accordance with any of the embodiments disclosed herein; e.g., any of the IC packages discussed below with reference to IC device assembly 2300 may take the form of any of the embodiments of IC package 2200 discussed above with reference to FIG. 17.

In some embodiments, circuit board 2302 may be a PCB including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package support.

FIG. 18 illustrates that, in some embodiments, IC device assembly 2300 may include a package-on-interposer structure 2336 coupled to first face 2340 of circuit board 2302 by coupling components 2316. Although not shown so as not to clutter the drawing, package-on-interposer structure 2336 may include a glass core 103, such as glass layer, in some embodiments. In other embodiments, package-on-interposer structure 2336 may not include a core. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. In some embodiments, IC package 2320 may include microelectronic assembly 100, and other components as described herein, which are not shown so as not to clutter the drawing. Coupling components 2318 may take any suitable form depending on desired functionalities, such as the forms discussed above with reference to coupling components 2316. In some embodiments, IC package 2320 may be or include IC package 2200, e.g., as described above with reference to FIG. 17.

Although a single IC package 2320 is shown in FIG. 18, multiple IC packages may be coupled to interposer 2304; indeed, additional interposers may be coupled to interposer 2304. Interposer 2304 may provide an intervening package support used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in FIG. 18, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group III-V and group IV materials. Interposer 2304 may include metal interconnects 2308 and vias 2310, including TSVs 2306. Interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

FIG. 19 is a block diagram of an example computing device 2400 that may include one or more components having one or more IC packages in accordance with any of the embodiments disclosed herein. For example, any suitable ones of the components of computing device 2400 may include microelectronic assembly 100 including glass in accordance with any of the embodiments disclosed herein. In another example, any one or more of the components of computing device 2400 may include any embodiments of IC package 2200 (e.g., as shown in FIG. 17). In yet another example, any one or more of the components of computing device 2400 may include an IC device assembly 2300 (e.g., as shown in FIG. 18).

A number of components are illustrated in FIG. 19 as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single SOC die.

Additionally, in various embodiments, computing device 2400 may not include one or more of the components illustrated in FIG. 19, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more digital signal processors (DSPs), ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-MRAM).

In some embodiments, computing device 2400 may include a communication chip 2412 (e.g., one or more communication chips; note that the terms “chip,” “die,” and “IC die” are used interchangeably herein). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives of it, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

The following paragraphs provide various examples of the embodiments disclosed herein.

Example 1 provides a microelectronic assembly, including a glass core having a first face, a second face opposite the first face, and an edge between an end of the first face and an end of the second face; and a layer of a material on the edge, where the material includes a fiber reinforced resin, a pre-impregnated dielectric, a pre-impregnated fabric, a carbon nanotube (CNT) reinforced epoxy resin, an ionogel, a mold material or a solder resist.

Example 2 provides the microelectronic assembly of example 1, where the material includes a fiber reinforced resin, a pre-impregnated dielectric, a pre-impregnated fabric, or a CNT reinforced epoxy resin and has a rounded or dome-shaped profile.

Example 3 provides the microelectronic assembly of example 1 or 2, where the material further extends at least partially on the first face and the second face of the glass core adjacent to the edge.

Example 4 provides the microelectronic assembly of any one of examples 1-3, further including a first substrate on the first face of the glass core, the first substrate including first conductive pathways through a first dielectric material and a first lateral surface, where the edge of the glass core protrudes from the first lateral surface; and a second substrate on the second face of the glass core, the second substrate including second conductive pathways through a second dielectric material and a second lateral surface, where the edge of the glass core protrudes from the second lateral surface.

Example 5 provides the microelectronic assembly of example 4, where the material includes a mold material or a solder resist and further extends on the first face of the glass core from the edge to the first lateral surface of the first substrate and on the second face of the glass core from the edge to the second lateral surface of the second substrate.

Example 6 provides the microelectronic assembly of any one of examples 1-5, where the material includes a fiber reinforced resin.

Example 7 provides the microelectronic assembly of any one of examples 1-6, where the material includes a pre-impregnated dielectric or a pre-impregnated fabric.

Example 8 provides the microelectronic assembly of any one of examples 1-7, where the material includes a CNT reinforced epoxy resin.

Example 9 provides the microelectronic assembly of any one of examples 1-8, where the material includes a mold material or a solder resist.

Example 10 provides the microelectronic assembly of any one of examples 1-9, where the material includes an ionogel.

Example 11 provides the microelectronic assembly of any one of examples 1-10, where the edge of the glass core is rectangular.

Example 12 provides the microelectronic assembly of any one of examples 1-11, where the edge of the glass core is angled.

Example 13 provides the microelectronic assembly of any one of examples 1-12, where the edge of the glass core has two sloping portions that taper out towards a middle of the glass core.

Example 14 provides the microelectronic assembly of any one of examples 1-13, further including a first substrate on the first face of the glass core, the first substrate including first conductive pathways through a first dielectric material and a first lateral surface that is co-planar with the edge of the glass core; and a second substrate on the second face of the glass core, the second substrate including second conductive pathways through a second dielectric material and a second lateral surface that is co-planar with the edge of the glass core.

Example 15 provides a microelectronic assembly, including a glass layer having a first face, a second face opposite the first face, and an edge between an end of the first face and an end of the second face; and a layer of a material on the edge, where the material includes a low-density polystyrene foam.

Example 16 provides the microelectronic assembly of example 15, where the material has a foam-like profile.

Example 17 provides the microelectronic assembly of example 15 or 16, where the material extends at least partially on the first face and the second face of the glass layer adjacent to the edge.

Example 18 provides the microelectronic assembly of any one of examples 15-17, further including a first substrate on the first face of the glass layer, the first substrate including first conductive pathways through a first dielectric material and a first lateral surface, where the edge of the glass layer protrudes from the first lateral surface; and a second substrate on the second face of the glass layer, the second substrate including second conductive pathways through a second dielectric material and a second lateral surface, where the edge of the glass layer protrudes from the second lateral surface.

Example 19 provides the microelectronic assembly of any one of examples 15-18, where a thickness of the glass layer is between 50 microns and 2 millimeters.

Example 20 provides a microelectronic assembly, including a glass core having a first face, a second face opposite the first face, and an edge between an end of the first face and an end of the second face; and a layer of a material on the edge, where the material includes a metal oxide.

Example 21 provides the microelectronic assembly of example 20, where a metal of the metal oxide includes aluminum (Al), magnesium (Mg), titanium (Ti), zinc (Zn), silicon (Si), boron (B), or lithium (Li).

Example 22 provides the microelectronic assembly of example 20 or 21, where the edge of the glass core is rounded.

Example 23 provides the microelectronic assembly of any one of examples 20-22, where a thickness of the glass core is between 50 microns and 2 millimeters.

Example 24 provides the microelectronic assembly of any one of examples 20-23, further including a first substrate on the first face of the glass core, the first substrate including first conductive pathways through a first dielectric material and a first lateral surface, where the edge of the glass core protrudes from the first lateral surface; and a second substrate on the second face of the glass core, the second substrate including second conductive pathways through a second dielectric material and a second lateral surface, where the edge of the glass core protrudes from the second lateral surface.

Example 25 provides the microelectronic assembly of example 24, further including through-glass vias (TGVs) in the glass core including a conductive material; the first conductive pathways in the first substrate electrically coupled to at least one of the TGVs; and the second conductive pathways in the second substrate electrically coupled to at least one of the TGVs.

Example 26 provides the microelectronic assembly of example 24 or 25, further including a die on the second substrate and electrically coupled to one or more of the second conductive pathways in the second substrate.

Example 27 provides the microelectronic assembly of example 26, further including an interconnect die at least partially within the second dielectric material of the second substrate and electrically coupled to the die.

Example 28 provides the microelectronic assembly of example 26 or 27, further including an insulating material surrounding the die.

Example 29 provides the microelectronic assembly of any one of examples 24-28, further including a circuit board at the first substrate and electrically coupled to one or more of the first conductive pathways.

1. A microelectronic assembly, comprising:
a glass core having a first face, a second face opposite the first face, and an edge between an end of the first face and an end of the second face; and
a layer of a material on the edge, wherein the material includes a fiber reinforced resin, a pre-impregnated dielectric, a pre-impregnated fabric, a carbon nanotube (CNT) reinforced epoxy resin, an ionogel, a mold material or a solder resist.

2. The microelectronic assembly of claim 1, wherein the material includes a fiber reinforced resin, a pre-impregnated dielectric, a pre-impregnated fabric, or a CNT reinforced epoxy resin and has a rounded or dome-shaped profile.

3. The microelectronic assembly of claim 1, wherein the material further extends at least partially on the first face and the second face of the glass core adjacent to the edge.

4. The microelectronic assembly of claim 1, further comprising:
a first substrate on the first face of the glass core, the first substrate including first conductive pathways through a first dielectric material and a first lateral surface, wherein the edge of the glass core protrudes from the first lateral surface; and
a second substrate on the second face of the glass core, the second substrate including second conductive pathways through a second dielectric material and a second lateral surface, wherein the edge of the glass core protrudes from the second lateral surface.

5. The microelectronic assembly of claim 4, wherein the material includes a mold material or a solder resist and further extends on the first face of the glass core from the edge to the first lateral surface of the first substrate and on the second face of the glass core from the edge to the second lateral surface of the second substrate.

6. The microelectronic assembly of claim 1, wherein the material includes a fiber reinforced resin.

7. The microelectronic assembly of claim 1, wherein the material includes a pre-impregnated dielectric or a pre-impregnated fabric.

8. The microelectronic assembly of claim 1, wherein the material includes a CNT reinforced epoxy resin.

9. The microelectronic assembly of claim 1, wherein the material includes a mold material or a solder resist.

10. The microelectronic assembly of claim 1, wherein the material includes an ionogel.

11. The microelectronic assembly of claim 1, wherein the edge of the glass core is rectangular.

12. The microelectronic assembly of claim 1, wherein the edge of the glass core is angled.

13. The microelectronic assembly of claim 1, wherein the edge of the glass core has two sloping portions that taper out towards a middle of the glass core.

14. A microelectronic assembly, comprising:
a glass layer having a first face, a second face opposite the first face, and an edge between an end of the first face and an end of the second face; and
a layer of a material on the edge, wherein the material includes a low-density polystyrene foam.

15. The microelectronic assembly of claim 14, wherein the material has a foam-like profile.

16. The microelectronic assembly of claim 14, wherein the material extends at least partially on the first face and the second face of the glass layer adjacent to the edge.

17. The microelectronic assembly of claim 14, further comprising:
a first substrate on the first face of the glass layer, the first substrate including first conductive pathways through a first dielectric material and a first lateral surface, wherein the edge of the glass layer protrudes from the first lateral surface; and
a second substrate on the second face of the glass layer, the second substrate including second conductive pathways through a second dielectric material and a second lateral surface, wherein the edge of the glass layer protrudes from the second lateral surface.

18. A microelectronic assembly, comprising:
a glass core having a first face, a second face opposite the first face, and an edge between an end of the first face and an end of the second face; and
a layer of a material on the edge, wherein the material includes a metal oxide.

19. The microelectronic assembly of claim 18, wherein a metal of the metal oxide includes aluminum (Al), magnesium (Mg), titanium (Ti), zinc (Zn), silicon (Si), boron (B), or lithium (Li).

20. The microelectronic assembly of claim 18, wherein the edge of the glass core is rounded.
